(19) United States
(12) Patent Application Publication
(10) Pub. No.: US 2026/0340245 A1
(43) Pub. Date: Oct. 29, 2026

(54) Semiconductor Metrology Enhanced By Process Based Decorrelation

(71) Applicant: KLA Corporation, Milpitas, CA (US)

(72) Inventors: Houssam Chouaib, Milpitas, CA (US); Vivek Kumar, Milpitas, CA (US)

(21) Appl. No.: 19/635,405

(22) Filed: Mar. 31, 2026

Related U.S. Application Data
(60) Provisional application No. 63/795,624, filed on Apr. 28, 2025.

(51) Int. Cl. G06F 30/3308

(52) U.S. Cl. CPC G06F 30/3308

(57) ABSTRACT

Methods and systems for model based measurement of a structural parameter characterizing a physical characteristic of a measurement target using a physics based measurement model with a trained Machine Learning (ML) based decorrelation model are presented herein. The physics based measurement model estimates values of multiple parameters characterizing multiple, different structural characteristics of a measurement target. The ML based decorrelation model estimates the value of one parameter of interest characterizing the target under measurement based on the values of the parameters estimated by the physics based measurement model, and optionally, the underlying measurement signals. The ML based decorrelation model is trained to leverage process-based correlation among the parameters estimated by the physics based measurement model to accurately estimate the value of one parameter of interest. In another aspect, a trained machine learning (ML) based POI seed model generates seed values for an iterative evaluation of the physics based measurement model.

### CROSS REFERENCE TO RELATED APPLICATION

The present application for patent claims priority under 35 U.S.C. § 119 from U.S. provisional patent application Ser. No. 63/795,624, entitled “Process guided scatterometry based metrology,” filed Apr. 28, 2025, the subject matter of which is incorporated herein by reference in its entirety.

### TECHNICAL FIELD

The described embodiments relate to metrology systems and methods, and more particularly to methods and systems for improved measurement accuracy.

### BACKGROUND INFORMATION

Semiconductor devices such as logic and memory devices are typically fabricated by a sequence of processing steps applied to a specimen. The various features and multiple structural levels of the semiconductor devices are formed by these processing steps. For example, lithography among others is one semiconductor fabrication process that involves generating a pattern on a semiconductor wafer. Additional examples of semiconductor fabrication processes include, but are not limited to, chemical-mechanical polishing, etch, deposition, and ion implantation. Multiple semiconductor devices may be fabricated on a single semiconductor wafer and then separated into individual semiconductor devices.

Process precision and repeatability depends on several factors introduced during the lithography and etching sequence and directly impacts Critical Dimensions (CDs). For example, uniformity of coating and baking, exposure time, develop technique, and etching directly impact CDs.

Metrology processes are used at various steps during a semiconductor manufacturing process to detect defects on wafers to promote higher yield. Optical and x-ray based metrology techniques offer the potential for high throughput without the risk of sample destruction. A number of techniques including scatterometry, ellipsometry, and reflectometry implementations and associated analysis algorithms are commonly used to characterize critical dimensions, film thicknesses, composition, overlay, and other parameters of nanoscale structures.

As devices (e.g., logic and memory devices) move toward smaller nanometer-scale dimensions, characterization becomes more difficult. Measurement precision requirements and the range of process control scale with device dimensions. Strict control of CDs is becoming more crucial as the geometric complexity of devices increases and dimensions continue to shrink. Within-wafer profiles, wafer to wafer variability, and lot-to-lot variations must be precisely tracked to correct unwanted process perturbations.

Devices incorporating complex three-dimensional geometry and materials with diverse physical properties contribute to characterization difficulty. For example, walls etched at subsequent process steps and bottom CDs exhibit roughness and non-uniformity that cause loss of optical signal.

In some examples, semiconductor devices are increasingly valued based on their energy efficiency, rather than speed alone. For example, energy efficient consumer products are more valuable because they operate at lower temperatures and for longer periods of time on a fixed battery power supply.

In other examples, energy efficient data servers are in demand to reduce their operating costs. As a result, there is a strong interest to reduce the energy consumption of semiconductor devices. Solutions include the use of high-K material layers and complex geometric structures, both of which contribute to characterization difficulty.

Moreover, as features sizes continue to shrink, the aspect ratio of device structures is increasing. This leads to more restrictive requirements on the control of feature profiles and their uniformity to reduce unwanted defects at current and down-stream process steps.

Shrinkage of feature sizes is not the only impediment to achieving adequate control of semiconductor target process accuracy. Measurement of parameters characterizing buried features is essential to determine contact dimensions in many memory and logic applications. The lack of uniformity and the position of buried features lower the measurement sensitivity of the CD to be controlled. Additionally, if process control is poor, unwanted correlations to other features further hinder optical sensitivity of the CD.

In general, a complex measurement model with multiple parameters is required to represent increasingly complex structures and account for process and dimensional variations. Complex, multiple parameter models include modeling errors induced by parameter correlations and low measurement sensitivity to some parameters. In addition, regression of complex, multiple parameter models having a relatively large number of floating parameter values may not be computationally tractable.

In some examples, a number of parameters are typically fixed in a model-based measurement to reduce the impact of these error sources and reduce computational effort. Although fixing the values of a number of parameters may improve calculation speed and reduce the impact of parameter correlations, it also leads to errors in the estimates of parameter values.

Spectroscopic Ellipsometry (SE) is a measurement technique employed to estimate critical dimensions of patterned wafers. A SE measurement system generates a beam of light with a known polarization state directed at a sample under measurement. The interaction of the incident illumination light with the sample under measurement induces changes in the polarization of light scattered from the sample. The changes in polarization are indicative of the structural characteristics of the sample, i.e., geometric and optical properties. The changes in polarization are analyzed across multiple illumination wavelengths. In this manner, a SE measurement system generates a spectrum of measurement signals indicative of the changes in polarization induced by the sample under measurement. In some examples, a rotating polarizer is employed in the illumination optical path. In some of these examples, a rotating analyzer is also employed in the collection optical path. These configurations enable dynamic polarization analysis that capture detailed signal information that is sensitive to the structural characteristics of the sample under measurement.

In some examples of SE, a Mueller Matrix (MM) methodology coupled with a finite-difference time-domain, finite element method and rigorous coupled-wave approximation (RCWA), offers signal information useful for the measurement of diverse CDs, including buried CDs. In many measurement applications, RCWA models offer a robust solution validated with real reference data. The measurement results enable the identification of process variations and unwanted excursions of multiple CDs within individual process steps.

In general, Mueller Matrix SE employing RCWA offers increased sensitivity to buried CDs, compared to many other measurement techniques. However, in practice, spectral signals sensitive to a particular buried CD are often screened by other parameters, i.e., correlation among multiple parameters impedes accurate resolution of a desired parameter of interest. This reduces the precision and accuracy of the measurement.

Measurement of CDs with acceptable precision is required to realize a sufficiently accurate RCWA model. If measurement sensitivity of the CD is affected by process correlations or hindered by features characterized by other parameters buried within the structure, e.g., deep trenches and bottom CDs, the achievable measurement precision associated with CDs of interest degrades enormously. This results in poor accuracy of reference tracking and unreliable reproducibility in the face of process variations.

Current RCWA based measurement techniques do not leverage process-based correlation between different parameters. Thus, current RCWA based measurement techniques fail to achieve sufficient measurement precision and accuracy. This often manifests in measurement results having poor correlation to reference data and high correlation to other geometric features.

Machine learning based measurement models offer an alternative approach to the measurement of parameters of interest. Model assist or modeless techniques based on machine learning based measurement models operating on raw measurement data have been employed to estimate values of parameters of interest. In some examples, machine learning based measurement models enable accurate measurements at high throughput.

Unfortunately, machine learning based measurement models operating on raw measurement data to directly estimate values of CDs require a large amount of training data to achieve accurate measurements. To realize high accuracy measurements of parameters of interest based on raw measurement data, large amounts of actual reference data is often required, i.e., reference data derived from actual measurements of the structures of interest by a trusted measurement system. Obtaining actual reference data is typically destructive, time-consuming, and expensive.

Currently, the solution of complex, multiple parameter measurement models often requires an unsatisfactory compromise. Current model reduction techniques are often unable to arrive at a measurement model that is both computationally tractable and sufficiently accurate for complex measurement applications. Moreover, complex, multiple parameter models make it difficult, or impossible, to optimize system parameter selections (e.g., wavelengths, angles of incidence, etc.) for each parameter of interest.

Future metrology applications present challenges due to increasingly small resolution requirements, multi-parameter correlation, increasingly complex geometric structures, and increasing use of opaque materials. Accordingly, it would be advantageous to develop high throughput systems and methods for characterizing complex semiconductor structures. In particular, it would be advantageous to develop a robust, reliable, and stable approach to in-line metrology of buried structures. Thus, methods and systems for improved measurements of semiconductor structures are desired.

### SUMMARY

Methods and systems for model based measurement of a structural parameter characterizing a physical characteristic of a measurement target using a physics based measurement model with a trained Machine Learning (ML) based decorrelation model are presented herein. The physics based measurement model estimates values of multiple parameters characterizing multiple, different structural characteristics of a measurement target. The values estimated by the physics based measurement model are provided to a trained ML based decorrelation model. The ML based decorrelation model estimates the value of one parameter of interest characterizing the target under measurement based on the values of the parameters estimated by the physics based measurement model.

The ML based decorrelation model is trained to leverage process-based correlation among the parameters estimated by the physics based measurement model to accurately estimate the value of one parameter of interest e.g., CD, film thickness, overlay, etc. In turn, this enables accurate estimation of the variation of parameters of interest within wafer and wafer-to-wafer. A ML based decorrelation model is trained over a range of process variations. This enables accurate measurements of values of parameters of interest that vary over time due to changes in process, e.g., process drift, process variation, etc. The robustness of the resulting measurements enables accurate measurement of process induced variations of one or more parameters of interest with reduced verification effort, i.e., fewer reference measurements performed by time-consuming and destructive reference measurement techniques such as SEM and TEM.

The methods and systems described herein are particularly beneficial in measurement applications with low measurement sensitivity, high correlation among structural parameters, relatively large process variation, etc. Exemplary measurement applications enhanced by the methods and systems described herein, include, but are not limited to, low sensitivity deep etch structures, buried structures, etc.

In some embodiments, a physics based measurement model is trained and subsequently employed to analyze measurement signals collected from scatterometry based metrology tools to estimate values of parameters of interest characterizing geometrical profiles and optical properties of a structure under measurement. A ML based decorrelation model is trained and subsequently employed to estimate values of one parameter of interest based on the values of multiple parameters of interest determined by the physics based measurement model. In some embodiments, multiple ML based decorrelation models are trained and each ML based decorrelation model is employed to estimate values of a different parameter of interest.

In one aspect, an ML based decorrelation model generates an estimated value of a single parameter of interest based on the values of multiple parameters characterizing the structure under measurement generated by a physics based measurement model. The ML based decorrelation model is trained to capture the process based correlations among parameters, and thus enhance the accuracy of an estimated value of a parameter of interest that has low process sensitivity. In this manner, the deficiency of an RCWA based analysis is overcome by leveraging the correlation among multiple parameters of interest embedded within a trained ML based decorrelation model.

In another aspect, an enhanced decorrelation measurement engine includes a trained machine learning (ML) based POI seed model to generate seed values for an iterative evaluation of a physics based measurement model. In some embodiments, a trained ML based POI seed model enhances measurement sensitivity and thus enable improved measurement precision and accuracy. Accurate seeding of values of parameters of a physics based measurement model reduces the number of iterations required in a regression analysis of the physics based model. In addition, accurate seeding significantly reduces the probability that the optimization process of a regression analysis of the physics based model becomes trapped in local minima, resulting in inaccurate and unpredictable estimation of parameter values.

In another further aspect, an ML based decorrelation model generates an estimated value of a single parameter of interest based on the values of the parameters of interest generated by the physics based measurement module and the underlying measurement signals. In this manner, correlations embedded in both the measurement signals and the parameters of interest are captured by the trained ML based decorrelation model.

In some embodiments, a dimension of the measurement signals is reduced, and the reduced, measurement signals are provided as input to the ML based decorrelation model, the physics based measurement model, or both.

In another further aspect, a seed model, a physics based measurement model, and a ML based decorrelation model are trained based on Design of Experiments (DOE) reference data sets including DOE measurements signals and corresponding values of one or more parameters of interest.

In another aspect, an enhanced decorrelation measurement engine is employed to generate DOE reference data. The DOE measurement signals and the values of one or more parameters of interest generated by the enhanced decorrelation measurement engine are employed as part of a DOE reference data employed to train a machine learning based measurement model that estimates values of one or more parameters of interest directly from measurement signals.

The foregoing is a summary and thus contains, by necessity, simplifications, generalizations and omissions of detail; consequently, those skilled in the art will appreciate that the summary is illustrative only and is not limiting in any way. Other aspects, inventive features, and advantages of the devices and/or processes described herein will become apparent in the non-limiting detailed description set forth herein.

### BRIEF DESCRIPTION OF THE DRAWINGS

FIG. 1 is a simplified diagram illustrative of an exemplary spectroscopic ellipsometer (SE) metrology system for performing measurements of one or more metrology targets using a machine learning based decorrelation model in accordance with the techniques described herein.

FIG. 2 is a diagram illustrative of a SE illumination beam incident on a wafer at a particular orientation described by an angle of incidence, θ, and an azimuth angle, φ.

FIG. 3 is a diagram illustrative of an enhanced decorrelation measurement engine in one embodiment.

FIG. 4 is a diagram illustrative of a POI seed model training engine in one embodiment.

FIG. 5 is a diagram illustrative of a physics based model training engine in one embodiment.

FIG. 6 is a diagram illustrative of a decorrelation model training engine in one embodiment.

FIG. 7 is a diagram illustrative of a perspective view of a one dimensional film stack employed to characterize thickness and material growth quality.

FIG. 8 is a diagram illustrative of a cross-sectional view of a two dimensional FinFET logic target employed to characterize various critical dimensions and thickness and material growth quality.

FIG. 9 is a diagram illustrative of perspective view of a three dimensional Gate All Around (GAA) logic target employed to characterize various critical dimensions and thickness and material growth quality.

FIG. 10 is a diagram illustrative of a cross-sectional view of a three dimensional memory target employed to characterize various critical dimensions and thickness and material growth quality.

FIG. 11 is a diagram illustrative of a top facing, cross-sectional view of the three dimensional memory target depicted in FIG. 10.

FIGS. 12A and 12B are plots illustrating an example of the tracking performance of a physics based measurement model and a physics based measurement model enhanced by a ML based decorrelation model, respectively, for values of a critical parameter characterizing a structural aspect of a GAA structure at a nanowire release process step.

FIGS. 13A and 13B are plots illustrating an example of the tracking performance of a physics based measurement model and a physics based measurement model enhanced by a ML based decorrelation model, respectively, for values of another critical parameter characterizing a structural aspect of a GAA structure at a nanowire release process step.

FIGS. 14A and 14B are plots illustrating an example of the tracking performance of a physics based measurement model and a physics based measurement model enhanced by a ML based decorrelation model, respectively, for values of a critical parameter characterizing a structural aspect of a GAA structure at a Silicon/Silicon Germanium release process step.

FIGS. 15A and 15B are plots illustrating an example of the tracking performance of a physics based measurement model and a physics based measurement model enhanced by a ML based decorrelation model, respectively, for values of another critical parameter characterizing a structural aspect of a GAA structure at a Silicon/Silicon Germanium release process step.

FIGS. 16A and 16B are plots illustrating an example of the tracking performance of a physics based measurement model and a physics based measurement model enhanced by a ML based decorrelation model, respectively, for values of a Top Critical Dimension (TCD) of a deep trench structure.

FIGS. 17A and 17B are plots illustrating an example of the tracking performance of a physics based measurement model and a physics based measurement model enhanced by a ML based decorrelation model, respectively, for values of a Bottom Critical Dimension (BCD) of a deep trench structure.

FIGS. 18A and 18B are plots illustrating an example of the tracking performance of a physics based measurement model and a physics based measurement model enhanced by a ML based decorrelation model, respectively, for values of in-die overlay in the x-direction.

FIGS. 19A and 19B are plots illustrating an example of the tracking performance of a physics based measurement model and a physics based measurement model enhanced by a ML based decorrelation model, respectively, for values of in-die overlay in the y-direction.

FIGS. 20A and 20B are plots illustrating an example of the tracking performance of a physics based measurement model and a physics based measurement model enhanced by a ML based decorrelation model, respectively, for values of a Tungsten Middle Critical Dimension (WMCD) of a DRAM memory structure.

FIGS. 21A and 21B are plots illustrating an example of the tracking performance of a physics based measurement model and a physics based measurement model enhanced by a ML based decorrelation model, respectively, for values of a Nitride layer Middle Critical Dimension (NitMCD) of a DRAM memory structure.

FIGS. 22A and 22B are plots illustrating an example of the tracking performance of a physics based measurement model and a physics based measurement model enhanced by a ML based decorrelation model, respectively, for values of a Nitride Height (NitHT) of a DRAM memory structure.

FIGS. 23A and 23B are plots illustrating an example of the tracking performance of a physics based measurement model and a physics based measurement model enhanced by a ML based decorrelation model, respectively, for values of a Poly Top Critical Dimension (PolyTCD) of a DRAM memory structure.

FIG. 24 is a flowchart illustrative of a method for model based measurement of a structural parameter characterizing a physical characteristic of a measurement target using a physics based measurement model with a trained Machine Learning (ML) based decorrelation model in one example.

### DETAILED DESCRIPTION

Reference will now be made in detail to background examples and some embodiments of the invention, examples of which are illustrated in the accompanying drawings.

Methods and systems for model based measurement of a structural parameter characterizing a physical characteristic of a measurement target using a physics based measurement model with a trained Machine Learning (ML) based decorrelation model are presented herein. The physics based measurement model estimates values of multiple parameters characterizing multiple, different structural characteristics of a measurement target. The values estimated by the physics based measurement model are provided to a trained ML based decorrelation model. The ML based decorrelation model estimates the value of one parameter of interest characterizing the target under measurement based on the values of the multiple parameters estimated by the physics based measurement model.

The ML based decorrelation model is trained to leverage process-based correlation among the parameters estimated by the physics based measurement model to accurately estimate the value of one parameter of interest e.g., CD, film thickness, overlay, etc. In turn, this enables accurate estimation of the variation of parameters of interest within wafer and wafer-to-wafer.

An ML based decorrelation model is trained over a range of process variations. This enables accurate measurements of values of parameters of interest that vary over time due to changes in process, e.g., process drift, process variation, etc. The robustness of the resulting measurements enables accurate measurement of process induced variations of one or more parameters of interest with reduced verification effort, i.e., fewer reference measurements performed by time-consuming and destructive reference measurement techniques such as SEM and TEM.

The methods and systems described herein are particularly beneficial in measurement applications with low measurement sensitivity, high correlation among structural parameters, relatively large process variation, etc. Exemplary measurement applications enhanced by the methods and systems described herein, include, but are not limited to, low sensitivity deep etch structures, buried structures, etc. Methods and systems described herein enable in-line monitoring of memory and logic devices to control process excursions at wafer level and across several nodes in the production of improved FinFET, GAA, CFET, DRAM and VNAND devices. In some examples, accurate monitoring and tracking of critical dimensions improves wafer yield and final electrical test performance of NMOS and PMOS devices.

In some embodiments, a physics based measurement model is trained and subsequently employed to analyze measurement signals collected from scatterometry based metrology tools to estimate values of parameters of interest characterizing geometrical profiles and optical properties of a structure under measurement. A ML based decorrelation model is trained and subsequently employed to estimate values of one parameter of interest based on the values of multiple parameters of interest determined by the physics based measurement model. Optical scatterometry based measurements using physics based measurement models and an ML based decorrelation model enable robust, high throughput measurements of buried, low sensitivity critical parameters by enhancing measurement sensitivity and breaking correlations among multiple parameters. In some embodiments, multiple ML based decorrelation models are trained and each ML based decorrelation model is employed to estimate values of a different parameter of interest.

In some embodiments, a Spectroscopic Ellipsometry (SE) system implements an RCWA based measurement model with a trained Machine Learning (ML) based decorrelation model to overcome poor sensitivity and improve measurement accuracy and robustness. An SE measurement system configured as described herein enables measurement of extremely low sensitivity CDs across the full wafer area based on measured spectral signatures. The enhanced measurement performance is enabled by accurate optical modeling and a trained ML based correlation model as described herein.

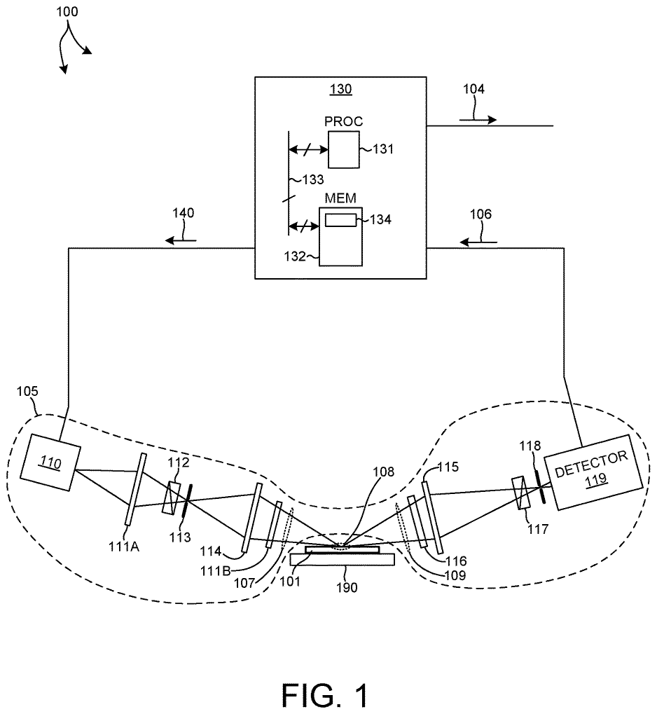

FIG. 1 depicts an exemplary spectroscopic ellipsometer (SE) metrology system 100 for performing SE measurements of one or more metrology targets in accordance with the techniques described herein. As depicted in FIG. 1, metrology system 100 includes a SE subsystem 105 including an illumination source 110 that generates a beam of SE illumination light 107 incident on wafer 101. In some embodiments, illumination source 110 is a broadband illumination source that emits illumination light in the ultraviolet, visible, and infrared spectra. In one embodiment, illumination source 110 is a laser sustained plasma (LSP) light source (a.k.a., laser driven plasma source). The pump laser of the LSP light source may be continuous wave or pulsed. Illumination source 110 can be a single light source or a combination of a plurality of broadband or discrete wavelength light sources. The light generated by illumination source 110 includes a continuous spectrum or parts of a continuous spectrum, from ultraviolet to infrared (e.g., vacuum ultraviolet to mid infrared). In general, illumination light source 110 may include a super continuum laser source, an infrared helium-neon laser source, an arc lamp, a globar source, or any other suitable light source.

In some embodiments, the amount of SE illumination light is broadband illumination light that includes a range of wavelengths spanning at least 500 nanometers. In one example, the broadband SE illumination light includes wavelengths below 250 nanometers and wavelengths above 750 nanometers. In general, the broadband SE illumination light includes wavelengths between 120 nanometers and 4,200 nanometers. In some embodiments, broadband illumination light including wavelengths beyond 4,200 nanometers, e.g., mid-infrared and far-infrared wavelengths, may be employed. In some embodiments, illumination source 110 includes a deuterium source emitting light with wavelengths across a range from 150 nanometers to 400 nanometers, a LSP source emitting light with wavelengths across a range from 180 nanometers to 2,500 nanometers, a supercontinuum source emitting light with wavelengths across a range from 400 nanometers to 4,200 nanometers, and a globar source emitting light with wavelengths across a range from 2,000 nanometers to 20,000 nanometers.

As depicted in FIG. 1, SE subsystem 105 includes an SE illumination subsystem configured to direct SE illumination light 107 to one or more structures formed on the wafer 101. The SE illumination subsystem is shown to include light source 110, illumination optics 111A, one or more optical filters 111B, polarizing component 112, illumination field stop 113, and illumination pupil aperture stop 114. As depicted, in FIG. 1, the beam of SE illumination light 107 passes through illumination optics 111A, optical filter(s) 111B, polarizing component 112, field stop 113, and aperture stop 114 as the beam propagates from the illumination source 110 to wafer 101. SE illumination light 107 illuminates a portion of wafer 101 over a measurement spot 108.

The illumination optics 111A conditions illumination light 107 and focuses SE illumination light 107 on measurement spot 108. The one or more optical filters 111B are used to control light level, spectral output, or combinations thereof, from the illumination subsystem. In some examples, one or more multi-zone filters are employed as optical filters 111B. Polarizing component 112 generates the desired polarization state exiting the illumination subsystem. In some embodiments, the polarizing component is a polarizer, a compensator, or both, and may include any suitable commercially available polarizing component. The polarizing component can be fixed, rotatable to different fixed positions, or continuously rotating. Although the SE illumination subsystem depicted in FIG. 1 includes one polarizing component, the SE illumination subsystem may include more than one polarizing component. Field stop 113 controls the field of view (FOV) of the SE illumination subsystem and may include any suitable commercially available field stop. Aperture stop 114 controls the numerical aperture (NA) of the SE illumination subsystem and may include any suitable commercially available aperture stop. The SE illumination subsystem may include any type and arrangement of illumination optics 111A, optical filter(s) 111B, polarizing component 112, field stop 113, and aperture stop 114 known in the art of spectroscopic ellipsometry.

Metrology system 100 also includes a collection optics subsystem configured to collect light resulting from the interaction between the one or more structures and the incident SE illumination light 107. A beam of collected light 109 is collected from measurement spot 108 by collection optics 115. Collected light 109 passes through collection aperture stop 116, polarizing element 117, and field stop 118 of the collection optics subsystem.

Collection optics 115 includes any suitable optical elements to collect light from the one or more structures formed on wafer 101. Collection aperture stop 116 controls the NA of the collection optics subsystem. Polarizing element 117 analyzes the desired polarization state. The polarizing element 117 is a polarizer or a compensator. The polarizing element 117 can be fixed, rotatable to different fixed positions, or continuously rotating. Although the collection subsystem depicted in FIG. 1 includes one polarizing element, the collection subsystem may include more than one polarizing element. Collection field stop 118 controls the FOV of the collection subsystem. The collection subsystem takes light from wafer 101 and directs the light through collection optics 115, aperture stop 116, and polarizing element 117 to be focused on collection field stop 118. In some embodiments, collection field stop 118 is used as a spectrometer slit for the spectrometers of the detection subsystem. However, collection field stop 118 may be located at or near a separate spectrometer slit of the spectrometers of the detection subsystem. The collection subsystem may include any type and arrangement of collection optics 115, aperture stop 116, polarizing element 117, and field stop 118 known in the art of spectroscopic ellipsometry.

In the embodiment depicted in FIG. 1, the collection optics subsystem directs light to detector 119. Detector 119 generates output responsive to light collected from the one or more structures illuminated by the SE illumination subsystem at measurement spot 108. In one example, detector 119 includes charge coupled devices (CCD) sensitive to ultraviolet and visible light (e.g., light having wavelengths between 190 nanometers and 860 nanometers). In other examples, detector 119 includes a photo detector array (PDA) sensitive to infrared light (e.g., light having wavelengths between 950 nanometers and 2500 nanometers). However, in general, detector 119 may include other detector technologies and arrangements (e.g., a position sensitive detector (PSD), an infrared detector, a photovoltaic detector, a quadrature cell detector, a camera, etc.). Each detector converts the incident light into electrical signals indicative of the spectral intensity of the incident light. In general, detector 119 generates SE measurement signals 103 indicative of the light detected on detector 119.

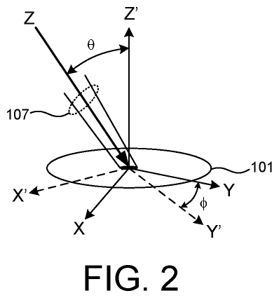

Each orientation of the SE illumination beam 107 relative to the surface normal of semiconductor wafer 101 is described by any two angular rotations of wafer 101 with respect to the illumination beam 107, or vice-versa. In one example, the orientation can be described with respect to a coordinate system fixed to the wafer. FIG. 2 depicts SE illumination beam 107 incident on wafer 101 at a particular orientation described by an angle of incidence, θ, and an azimuth angle, φ. Coordinate frame XYZ is fixed to the SE metrology system (e.g., SE illumination beam 107) and coordinate frame X′Y′Z′ is fixed to wafer 101. The Y axis is aligned in plane with the surface of wafer 101. X and Z are not aligned with the surface of wafer 101. Z′ is aligned with an axis normal to the surface of wafer 101, and X′ and Y′ are in a plane aligned with the surface of wafer 101. As depicted in FIG. 2, SE illumination beam 107 is aligned with the Z-axis and thus lies within the XZ plane. Angle of incidence, θ, describes the orientation of the SE illumination beam 107 with respect to the surface normal of the wafer in the XZ plane. Furthermore, azimuth angle, φ, describes the orientation of the XZ plane with respect to the X′Z′ plane. Together, θ and φ, uniquely define the orientation of the SE illumination beam 107 with respect to the surface of wafer 101. In this example, the orientation of the SE illumination beam with respect to the surface of wafer 101 is described by a rotation about an axis normal to the surface of wafer 101 (i.e., Z′ axis) and a rotation about an axis aligned with the surface of wafer 101 (i.e., Y axis).

As illustrated in FIG. 1, SE metrology tool 100 includes a specimen positioning system 190 configured to both align specimen 101 and orient specimen 101 over a large range of angles of incidence and azimuth angle with respect the illumination beam 107. In this manner, measurements of specimen 101 are collected by metrology system 100 over any number of locations and orientations on the surface of specimen 101. In one example, computing system 130 communicates command signals (not shown) to specimen positioning system 190 that indicate the desired position of specimen 101. In response, specimen positioning system 190 generates command signals to the various actuators of specimen positioning system 190 to achieve the desired positioning of specimen 101.

In general, specimen positioning system 190 may include any suitable combination of mechanical elements to achieve the desired linear and angular positioning performance, including, but not limited to goniometer stages, hexapod stages, angular stages, and linear stages.

In general, an optical scatterometer, such as SE metrology system 100 is configured to deliver illumination light to a metrology target under measurement at any desired angle of incidence and azimuth angle.

Collected light is spatially dispersed across a detector array according to wavelength. Light from each narrow band of wavelengths is incident on a different pixel of the detector array. The detected light signal at each narrow band of wavelengths is measured simultaneously by a multiplexed readout of the pixels. The detected intensities are transformed into a set of detected SE measurement signals 106 in accordance with the particular SE measurement technique implemented by the SE subsystem.

In general, the detected SE measurement signals 106 depend on the configuration of the SE subsystem. In some embodiments, the detected SE measurement signals are SE harmonic signals, e.g., {α, β}, {ψ, Δ}, etc. In some embodiments the detected SE measurement signals are one or more elements of the Mueller Matrix representation of the SE measurement. In general, any detected SE measurement signal sensitive to changes in optical polarization may be contemplated within the scope of this patent document.

Metrology system 100 also includes computing system 130 configured as an enhanced decorrelation measurement engine 200 configured to estimate values of one or more parameters of interest 104 characterizing a structure under measurement using RCWA model based measurement techniques together with a trained Machine Learning (ML) based decorrelation model based on the detected SE measurement signals 106.

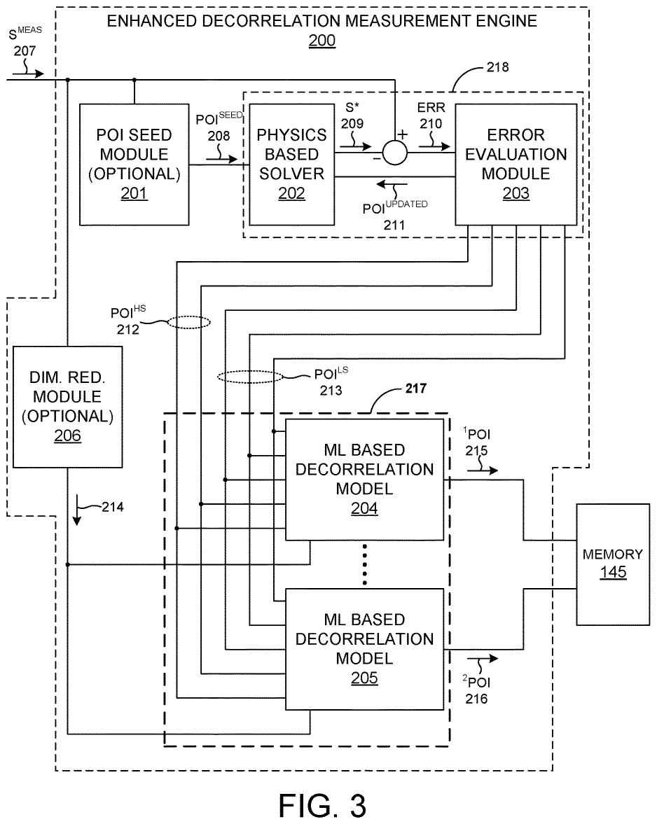

FIG. 3 is a diagram illustrative of an enhanced decorrelation measurement engine 200 in one embodiment. As depicted in FIG. 3, enhanced decorrelation measurement engine 200 includes an optional POI seed module 201, physics based measurement module 218, error evaluation module 203, an optional dimension reduction module 206, and ML based decorrelation module 217 including one or more ML based decorrelation models. As depicted in FIG. 3, measurement signals, S^{MEAS} 207, generated by a measurement system, e.g., detected SE measurement signals 106 depicted in FIG. 1, are provided to enhanced decorrelation measurement engine 200.

In one aspect, an enhanced decorrelation measurement engine includes a trained machine learning (ML) based POI seed model to generate seed values for an iterative evaluation of a physics based measurement model. In some embodiments, a trained ML based POI seed model enhances measurement sensitivity and thus enable improved measurement precision and accuracy. Accurate seeding of values of parameters of a physics based measurement model reduces the number of iterations required in a regression analysis of the physics based model. In addition, accurate seeding significantly reduces the probability that the optimization process of a regression analysis of the physics based model becomes trapped in local minima, resulting in inaccurate and unpredictable estimation of parameter values. In some embodiments, the POI seed model is a trained machine learning based model trained to generate estimated values of one or more parameters floated in the evaluation of the physics based measurement model based on the measurement signals generated by the measurement system, e.g., SE measurement signals 106 depicted in FIG. 1. In some embodiments, the one or more parameters generated by the POI seed model include both floated and fixed valued parameters employed in the evaluation of the physics based measurement model.

In one example, measurement signals, S^{MEAS} 207, are provided to POI seed module 201. POI seed module 201 includes a machine learning based model trained to generate seed values for one or more parameters, POI^{SEED} 208, based on measurement signals generated by a metrology system, e.g., detected SE measurement signals 106. The seed values, POI^{SEED} 208, are provided to physics based measurement module 218. Although the embodiment depicted in FIG. 3 includes POI seed module 201, in general, POI seed module is optional. In other embodiments, seed values may be generated without reference to the measured signals, e.g., random selection, best estimates provided by a user, historical values, etc.

Physics based measurement module 218 includes a physics based solver 202 and error evaluation module 203. Physics based solver 202 includes a physics based measurement model characterizing the structure under measurement and an electromagnetic solver employed to simulate the interaction of the modeled structure with the incident illumination light. In preferred embodiments, the simulation of the measurement signals generated by the interaction of the modeled structure with the incident illumination light is achieved by solving Maxwell's equations for the modeled structure under measurement. Maxwell's equations represent the interaction between incident illumination light and the structure under measurement. Maxwell's equations are solved for a particular measurement using one or more electro-magnetic solvers. Exemplary electro-magnetic solvers include, but are not limited to, a finite element method, a method of moments, a surface integral method, a volume integral method, a rigorous coupled-wave analysis (RCWA), and a finite-difference time domain method.

In general, the resulting electric field, E, associated with the interaction of an incident electric field, E_{inc}, with the structure under measurement is modelled as coupled diffracted orders as illustrated by Equation (1), where x and z are spatial coordinates, Rₘ are the diffraction amplitudes, θ, is the Angle of Incidence (AOI), λ, is the wavelength of incident light, ε, is the structure dielectric function, p is the pitch of the periodic structure under measurement, and m is the diffraction order.

$$E ( r , λ ) = {E}_{inc} exp ( ikx - iqz ) + {\sum }_{m} {R}_{m} ( ε , λ ) exp ( {ik}_{m} x + {iq}_{m} z ) \qquad ( 1 )$$

$$k = \frac{2 π}{λ} sin θ ; q = \frac{2 π}{λ} cos θ ; {q}_{m} = \sqrt{{( \frac{2 π}{λ} )}^{2} - {k}_{m}^{2}} ; and {k}_{m} = k + \frac{2 π}{p}$$

When the wavelength of incident light exceeds the pitch of the structure under measurement, only zeroth order signal, R₀, is captured at the detector and higher orders are coupled to the zeroth order. When the wavelength of incident light is less than the pitch of the structure under measurement, signals at multiple diffraction orders are captured at the detector.

In many examples, Maxwell's equations are solved with the structure dielectric function, ε, expanded as a Fourier series as illustrated by Equation (2).

ε(x,z)=Σₘεₘ(z)exp(ikₘx) (2)

The representation of the dielectric function as a Fourier series illustrated by Equation (2) assumes the electric field interacts with a spatially periodic structure. The Fourier series incorporates the geometric model of the structure under measurement including the material dispersion properties of the elements of the structure under measurement. The geometric model is parameterized by various geometric dimensions, e.g., pitch, heights of various structural elements, critical dimensions of various structural elements, and other shape profile features.

In general, it is preferred to measure and analyze periodic structures, or quasi-periodic structures that are approximated as periodic structures. The diffracted signals scattered from a periodic structure are amplified by the square of the number of scattering centers. Moreover, the solution of Maxwell's equations is more efficiently executed in the frequency domain.

By way of example, Rₘ can be expressed as illustrated in Equation (3) for a structure parameterized by j different critical dimensions and k different height dimensions, where j and k are any non-negative integer values.

Rₘ=Rₘ(AOI,λ,ε(CD₁,CD₂, . . . ,CDⱼ,HT₁,HT₂, . . . ,HTₖ) (3)

In one example, the polarization states of the electric field, E, described by Equation (1) are represented by the Stokes vector illustrated by Equation (4), where Sᵢₙ is the electric field polarization state of the incident illumination beam, Sₒᵤₜ is the electric field polarization state of the scattered beam, and M is the measured sample operator characterizing the transition from the incident polarization state, Sᵢₙ, to the scattered polarization state, Sₒᵤₜ.

Sₒᵤₜ(AOI,λ,CD1,CD2,CD3,HT1,HT2,HT3)=M(AOI,λ,CD1,CD2,CD3,HT1,HT2,HT3)·Sᵢₙ(AOI,λ) (4)

The most generalized form of the measured sample operator for a spectroscopic ellipsometry measurement is the Mueller Matrix illustrated by Equation (5). The Mueller Matrix captures all of the polarization states.

$$M = [ \begin{matrix}{m}_{00} & {m}_{01} & {m}_{02} & {m}_{03} \\ {m}_{10} & {m}_{11} & {m}_{12} & {m}_{13} \\ {m}_{20} & {m}_{21} & {m}_{22} & {m}_{23} \\ {m}_{30} & {m}_{31} & {m}_{32} & {m}_{33}\end{matrix} ] \qquad ( 5 )$$

In some examples, the simulated measurement signals, S* 209, generated by the physics based solver 202 include the simulated signals, e.g., spectra, comprising the elements of the Mueller Matrix based on the assumed values of the parameters of the physics based measurement model. In some embodiments, physics based solver 202 includes an RCWA solver to solve Maxwell's equations and generate simulated measurement signals, S* 209. However, in other examples, the simulated measurement signals may be expressed in any other suitable format, e.g., SE harmonic signals {α, β} or {γ, Δ}, etc.

As depicted in FIG. 3, simulated measurement signals, S* 209, are compared to the measured signals, S^{MEAS} 207. A metrology system, e.g., SE system 100 depicted in FIG. 1, generates measured signals, S^{MEAS} 207, from the detected intensities of light scattered from the structure under measurement. In some embodiments, the sixteen components of the Mueller Matrix are determined directly from the detected intensities. The signals, e. g., spectra, associated with each element of the Mueller Matrix are a function of the wavelength, angle of incidence, and the topography and material properties of the structure under measurement. Different wavelengths, different angles of incidence, and different Mueller Matrix elements, i.e., different polarization states, exhibit unique responses to specific feature variations, and thus greater measurement sensitivity compared to other representations of SE measurement signals.

In some embodiments, measurements are performed over a range of angles of incidence and a range of illumination wavelengths to generate a full Mueller matrix from the detected intensities.

As depicted in FIG. 3, physics based solver 202 and error evaluation module 203 operate together to mathematically define the structure under measurement and estimate parameter values characterizing material properties and geometric features of the structure under measurement from measured spectra.

As depicted in FIG. 3, error signals, ERR 210, characterizing a difference between the measured signals, S^{MEAS} 207, and the simulated measurement signals, S* 209, are determined. The error signals, ERR 210, are communicated to error evaluation module 203. Error evaluation module 203 analyzes the error signals, ERR 210, and generates updated values of the floating parameters, POI^{UPDATED} 211. The updated values of the floating parameters, POI^{UPDATED} 211, are provided to the physics based solver 202. The measurement model is reevaluated based on the updated values to generate updated, simulated measurement signals, S* 209. Error signals, ERR 210, characterizing the difference between the measured signals, S^{MEAS} 207, and updated, simulated measurement signals, S* 209, are determined. The updated error signals, ERR 210, are communicated to error evaluation module 203 for analysis. This iterative sequence of steps is repeated until the error signals, ERR 210, fall below a predetermined threshold or the number of iterations reaches a threshold value. At the conclusion of the iterative analysis, the resulting values of the parameters of interest are communicated to the ML based decorrelation module 217.

In general, error evaluation module 203 includes the implementation of one or more data fitting and optimization techniques, including, but not limited to a measurement library, a fast-reduced-order model, regression, and a machine learning based estimator.

In general, a structure under measurement, e.g., a grating structure, is characterized by a number of different parameters of interest, e.g., CD, sidewall angle, height, etc. When evaluating a physics based model using an electromagnetic solver, e.g., RCWA, the parameters are floated independently. However, in reality, the parameters are correlated because one or more fabrication processes often affect multiple parameters in a repeatable manner. For example, an etch process step affects both the inner spacer and gate spacer of a GAA structure. However, the gate spacer is much more sensitive to the etch process step. When evaluating a physics based model using RCWA, the thickness of both the inner spacer and the gate spacer are floated. The estimated value of thickness for the gate spacer may be accurately estimated, but the estimated thickness of the inner spacer is often inaccurately estimated because the model fitting error induced by the inner spacer thickness is not sufficiently distinguished from the model fitting error induced by the gate spacer thickness.

In another aspect, an ML based decorrelation model is trained to capture the process based correlations among parameters, and thus enhance the accuracy of an estimated value of a parameter of interest that has low process sensitivity. In this manner, the deficiency of an RCWA based analysis is overcome by leveraging the correlation among multiple parameters of interest embedded within a trained ML based decorrelation model.

As depicted in FIG. 3, the values of the parameters of interest estimated by iterative solution of a physics based measurement model include both high sensitivity parameters of interest, POI^{HS} 212 and low sensitivity parameters of interest, POI^{LS} 213. The estimated values of low sensitivity parameters of interest are generally not sufficiently accurate.

In a further aspect, an ML based decorrelation model generates an estimated value of a single parameter of interest based on the values of the parameters of interest generated by the physics based measurement module. In general, a ML based decorrelation module, e.g., ML based decorrelation module 217 includes one or more ML based decorrelation models, each trained to estimate values of a different parameter of interest. As depicted in FIG. 3, ML based decorrelation model 204 generates an estimated value of a single parameter of interest, ¹POI 215, based on the values of the high sensitivity parameters of interest, POI^{HS} 212 and low sensitivity parameters of interest, POI^{LS} 213. Similarly, ML based decorrelation model 205 generates an estimated value of another single parameter of interest, ²POI 216, based on the values of the high sensitivity parameters of interest, POI^{HS} 212 and low sensitivity parameters of interest, POI^{LS} 213. The estimated values ¹POI 215 and ²POI 216 are communicated to a memory, e. g., memory 145. In some examples, each of the single parameters of interest, ¹POI 215 and ²POI 216 correspond to a different low sensitivity parameter of interest inaccurately estimated by the physics based measurement module 218, i.e., ¹POI 215 is the same parameter as one the low sensitivity parameter of interest, POI^{LS} 213, and ²POI 216 is the same parameter as another low sensitivity parameter of interest, POI^{LS} 213. In these examples, each ML based decorrelation model generates an enhanced estimated value of one of the low sensitivity parameters of interest. In other examples, an estimated value of a single parameter of interest generated by an ML based decorrelation model does not correspond directly to any of the parameters of interest determined by the physics based measurement module.

In another further aspect, an ML based decorrelation model generates an estimated value of a single parameter of interest based on the values of the parameters of interest generated by the physics based measurement module and the underlying measurement signals. As depicted in FIG. 3, ML based decorrelation model 204 generates an estimated value of a single parameter of interest, ¹POI 215, based on the values of the high sensitivity parameters of interest, POI^{HS} 212 and low sensitivity parameters of interest, POI^{LS} 213, and the measurement signals, S^{MEAS} 207. In these embodiments, ML based decorrelation model 204 is trained based on estimated values of parameters of interest generated by a physics based measurement model and the measurement signals. In this manner, correlations embedded in both the measurement signals and the parameters of interest are captured by the trained ML based decorrelation model. In general, the estimation of a parameter of interest by an ML based decorrelation model based on both measurement signals and values of parameters of interest generated by a physics based measurement module is optional.

In some embodiments, a dimension of the measurement signals, S^{MEAS} 207, is reduced, and the reduced, measurement signals 214 are provided to the ML based decorrelation module 217, the physics based measurement module 218, or both. For example, as depicted in FIG. 3, dimension reduction module 206 receives measurement signals, S^{MEAS} 207, and generates reduced, measurement signals 214 based on measurement signals, S^{MEAS} 207. In some embodiments, dimension reduction module 206 implements a data reduction algorithm, e.g., principal component analysis, singular value decomposition, etc., to reduce the dimension of the measured signals. In general, data reduction is optional.

In a further aspect, various elements of an enhanced decorrelation measurement engine are trained based on Design of Experiments (DOE) reference data sets including DOE measurements signals and corresponding values of one or more parameters of interest. For example, the POI seed model, the physics based measurement model, and each ML based decorrelation model of enhanced decorrelation measurement engine 200 depicted in FIG. 3 are trained based on DOE reference data sets.

Each set of DOE reference data includes DOE measurement signals associated with a measurement of a DOE measurement target by a nominal instance of a metrology system for which the elements of the enhanced decorrelation measurement engine is trained, and corresponding values of one or more parameters of interest associated with each measured DOE measurement target.

DOE reference data is acquired from one or more reference data sources. Reference data sources are measurement data sources that generate measurement values that are trusted to be sufficiently accurate. In general, DOE measurement signals are generated by a nominal instance of a metrology system for which the elements of the enhanced decorrelation measurement engine is trained, e.g., the metrology system itself or another metrology system in the same nominal configuration as the metrology system itself. In some embodiments, corresponding values of one or more parameters of interest characterizing the measured DOE metrology targets are measured by a different metrology system, e.g., a transmission electron microscope (TEM), a scanning electron microscope (SEM), an atomic force microscope (AFM), a small-angle x-ray scatterometer (SAXS), etc. In some examples, the DOE reference data is generated based on actual measurements. However, in some other examples, DOE reference data is generated synthetically, i.e., generated by simulation. Generating DOE reference data synthetically enables exploration of a wider range of process conditions and generally is much less time consuming and expensive compared to performing actual reference measurements. In particular, reference measurements performed using destructive techniques, e.g., TEM, SEM, and AFM, are particularly time consuming and expensive.

In some examples, DOE reference data includes data collected from multiple, different reference data sources. In some examples, DOE reference data includes both actual and synthetically generated reference data. In some examples, DOE reference data includes actual reference data collected by multiple, different reference measurement systems, e.g., reference data from TEM, SEM and SAXS systems. Typically, in these examples, a calibration is required. In one example, reference data collected from a SAXS tool is calibrated with reference data collected from a TEM tool. The calibrated reference data collected from the SAXS tool and the reference data collected from the TEM tool are employed as part of the DOE reference data set for model training.

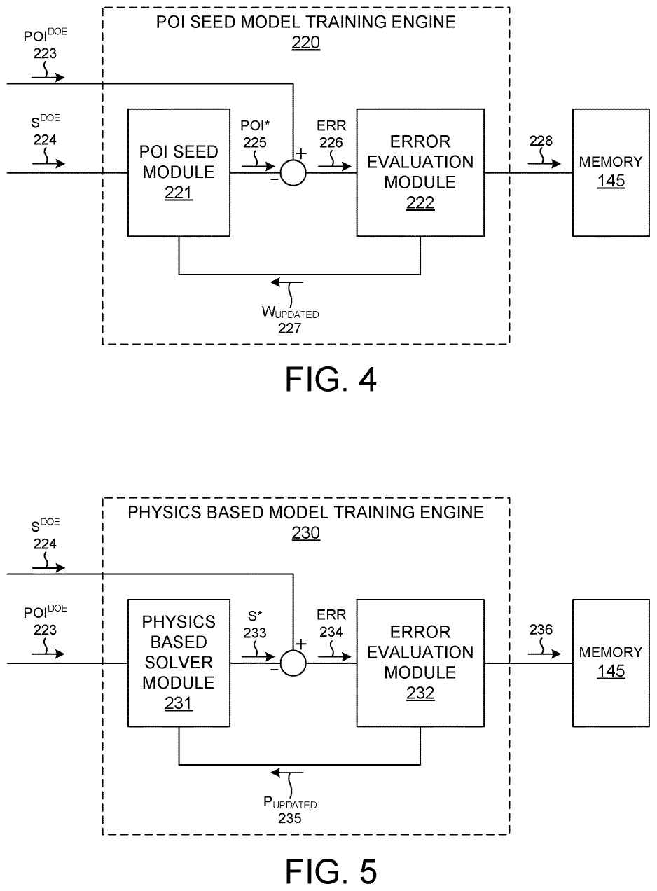

FIG. 4 is a diagram illustrative of a POI seed model training engine 220 in one embodiment. As depicted in FIG. 4, POI seed model training engine 220 includes POI seed module 221 and error evaluation module 222. As depicted in FIG. 4, DOE measurement signals, S^{DOE} 224, and corresponding values of one or more parameters of interest, POI DOE 223 are provided to POI seed model training engine 220. POI seed module 221 includes a ML based POI seed model. As depicted in FIG. 4, the ML based POI seed model generates estimated values of one or more parameters of interest, POI* 225 based on DOE measurement signals, S^{DOE} 224. Error signals, ERR 226, characterize a difference between the DOE values of the parameter of interest, POI^{DOE} 223, and the estimated values of one or more parameters of interest, POI* 225, generated by the ML based POI seed model. Error evaluation module 222 analyzes the error signals, ERR 226, and generates updated values of the weighting parameters of the ML based POI seed model, W_{UPDATED} 227. The updated values, W_{UPDATED} 227, are communicated to POI seed module 221. The ML based POI seed model generates updated estimated values of one or more parameters of interest, POI* 225 based on DOE measurement signals, S^{DOE} 224, using the updated values of the weighting parameters, W_{UPDATED} 227. Error signals, ERR 226, characterizing the difference between the DOE values of the parameter of interest, POI DOE 223, and the updated, estimated values of one or more parameters of interest, POI* 225, are determined. The updated error signals, ERR 226, are communicated to error evaluation module 222 for analysis. This iterative sequence of steps is repeated until the error signals, ERR 226, fall below a predetermined threshold or the number of iterations reaches a threshold value. At the conclusion of the iterative analysis, the resulting trained POI seed model 228 is communicated to and stored in a memory, e.g., memory 145.

FIG. 5 is a diagram illustrative of a physics based model training engine 230 in one embodiment. As depicted in FIG. 5, physics based model training engine 230 includes physics based solver module 231 and error evaluation module 232. As depicted in FIG. 5, DOE measurement signals, S^{DOE} 224, and corresponding values of one or more parameters of interest, POI^{DOE} 223 are provided to physics based model training engine 230. Physics based solver module 231 includes a physics based model of the physical interaction of the structure under measurement and the incidence illumination. As depicted in FIG. 5, the physics based measurement model generates simulated measurement signals, S* 233, generated by the specified metrology system in response to a measurement of a structure parameterized by the values of one or more parameters of interest, POI^{DOE} 223. Error signals, ERR 234, characterize a difference between the DOE measurement signal values, S^{DOE} 224, and the simulated measurement signals, S* 233. Error evaluation module 232 analyzes the error signals, ERR 234, and generates updated values of one or more of the fixed valued model parameters of the physics based measurement model, P_{UPDATED} 235. The updated values, P_{UPDATED} 235, are communicated to physics based solver module 231. The physics based solver module generates updated, simulated measurement signals, S* 233, based on the DOE values of one or more parameters of interest, POI^{DOE} 223, using the updated values of the model parameters, P_{UPDATED} 235. Error signals, ERR 234, characterizing the difference between the DOE measurement signal values, S^{DOE} 224, and the updated, simulated measurement signals, S* 233, are determined. The updated error signals, ERR 234, are communicated to error evaluation module 232 for analysis. This iterative sequence of steps is repeated until the error signals, ERR 232, fall below a predetermined threshold or the number of iterations reaches a threshold value. At the conclusion of the iterative analysis, the resulting trained physics based measurement model 236 is communicated to and stored in a memory, e.g., memory 145.

In general, one or more physics based measurement models are trained for a particular measurement application. A physics based measurement model is created based on the known geometry, materials, and nominal values of the target structure. In general, one physics based measurement model could be generated and tuned to predict multiple parameter of interest, or multiple physics based measurement models could be generated and tuned, each employed to predict a different parameter of interest. In general, the optimization of a physics based measurement model may be performed manually or automatically via a solution optimizer engine, e.g., physics based model training engine 230.

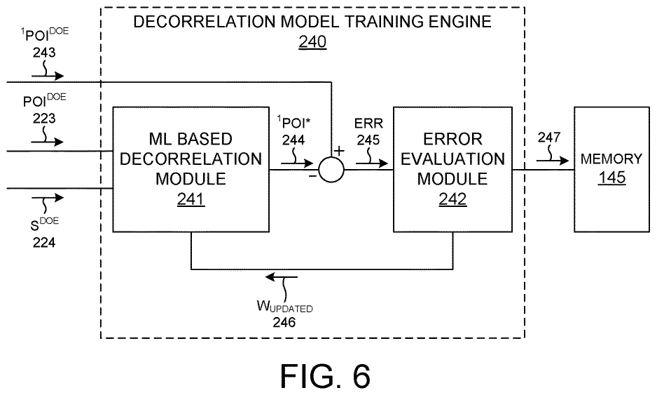

FIG. 6 is a diagram illustrative of a decorrelation model training engine 240 in one embodiment. As depicted in FIG. 6, decorrelation model training engine 240 includes ML based decorrelation module 241 and error evaluation module 242. As depicted in FIG. 6, DOE measurement signals, S^{DOE} 224, and corresponding values of one or more parameters of interest, POI^{DOE} 223 are provided to decorrelation model training engine 240. ML based decorrelation module 241 includes a ML based decorrelation model. As depicted in FIG. 6, the ML based decorrelation model generates estimated values of one parameter of interest, ¹POI* 244 based on the DOE values of one or more parameters of interest, POI^{DOE} 223, and optionally, DOE measurement signals, S^{DOE} 224. Error signals, ERR 245, characterize a difference between the DOE value of the one parameter of interest, ¹POI^{DOE} 243, and the estimated value of the one parameter of interest, ¹POI* 244, generated by the ML based decorrelation model. Error evaluation module 242 analyzes the error signals, ERR 245, and generates updated values of the weighting parameters of the ML based decorrelation model, W_{UPDATED} 246. The updated values, W_{UPDATED} 246, are communicated to ML based decorrelation module 241. The ML based decorrelation model generates updated estimated values of one parameter of interest, ¹POI* 244 based on the DOE values of one or more parameters of interest, POI^{DOE} 223, and optionally, DOE measurement signals, SDE 224, using the updated values of the weighting parameters, W_{UPDATED} 246. Error signals, ERR 245, characterizing the difference between the DOE value of the one parameter of interest, ¹POI^{DOE} 243, and the updated, estimated value of the one parameter of interest, ¹POI* 244, is determined. The updated error signals, ERR 245, are communicated to error evaluation module 242 for analysis. This iterative sequence of steps is repeated until the error signals, ERR 245, fall below a predetermined threshold or the number of iterations reaches a threshold value. At the conclusion of the iterative analysis, the resulting trained ML based decorrelation model 247 is communicated to and stored in a memory, e.g., memory 145.

In general, a ML based decorrelation model is trained for each parameter of interest for which it is desirable to enhance measurement sensitivity. In general, parameters of interest generated by a physics based measurement model and other floating parameters of the physics based model may be provided as inputs to a ML based decorrelation model during both training and inference. In many examples, the additional parameters improve model robustness by providing additional signal information indicative of process-based correlation among all parameters.

In some examples, POI seed model training, physics measurement model tuning, and ML based decorrelation model training as illustrated in FIGS. 4-6, are performed independently. However, in some other examples, POI seed model training, physics measurement model tuning, ML based decorrelation model training, or any combination thereof, is performed together as part of an integrated workflow. For example, in one example, an integrated workflow includes POI seed model training, followed by tuning of a physics based measurement model using seed values of one or more model parameters generated by the trained POI seed model. After, tuning of the physics based measurement model, one or more ML based decorrelation models are trained. In some of these examples, one or more ML based decorrelation models are trained using DOE data sets generated by the tuned physics based measurement model.

In another aspect, an enhanced decorrelation measurement engine is employed to generate DOE reference data. The DOE reference data includes DOE measurement signals associated with a measurement of a DOE measurement target by a nominal instance of a metrology system for which the elements of the enhanced decorrelation measurement engine is trained, and corresponding values of one or more parameters of interest associated with each measured DOE measurement target. In some embodiments, DOE measurement signals are collected from a metrology system for which the elements of an enhanced decorrelation measurement engine are trained. Furthermore, an enhanced decorrelation measurement engine, e.g., enhanced decorrelation measurement engine 200, is employed to generate values of one or more parameters of interest characterizing each measured target. The DOE measurement signals and the values of one or more parameters of interest estimated by the enhanced decorrelation measurement engine are employed as part of a DOE reference data employed to train a machine learning based measurement model, in addition to, or in lieu of, DOE reference data generated from one or more reference measurement systems.

Regression on physics based measurement models is computationally intensive, and the computational cost may not be acceptable in some measurement applications, e.g., some high volume manufacturing applications where speed to solution is paramount. In these examples, it may be desirable to train a machine learning based measurement model that estimates values of one or more parameters of interest directly from measurement signals. However, training a machine learning based measurement model that estimates values of one or more parameters of interest directly from measurement signals with sufficient accuracy requires a large quantity of DOE measurement data. For many advanced technology nodes, it is not possible to generate the required quantity of DOE measurement data from measurements performed by trusted, reference measurement tools. In these examples, accurate measurements of one or more parameters of interest estimated by an enhanced decorrelation measurement engine enable the generation DOE reference data sets sufficient to train machine learning based measurement models that estimate values of one or more parameters of interest directly from measurement signals with sufficient accuracy.

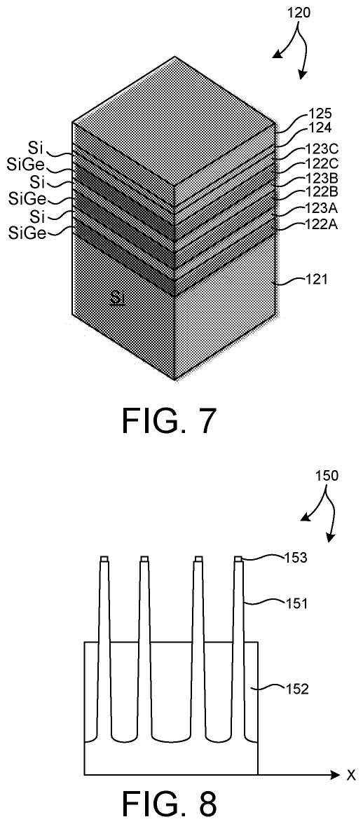

Measurements performed with a ML based decorrelation model combined with a physics based measurement model as described herein enable improved measurement performance for a number of different measurement applications involving many different measurement targets, e.g., measurement targets exhibited in FIGS. 7-11.

FIG. 7 is a diagram illustrative of a perspective view of a one dimensional film stack 120 employed to characterize thickness and material growth quality. As depicted in FIG. 7, three alternating layers of Silicon Germanium 122A-C and Silicon 123A-C are fabricated on a Silicon substrate 121. An oxide layer 124 such as Silicon oxide and a Silicon nitride layer 125 are fabricated on top of the SiGe/Si superlattice stack.

FIG. 8 is a diagram illustrative of a cross-sectional view of a two dimensional FinFET logic target 150 employed to characterize various critical dimensions and thickness and material growth quality. The two dimensional FinFET logic target 150 exhibits periodicity in the x direction. As depicted in FIG. 8, FinFET logic target includes fin structures 151, a fill layer 152, and a nitride layer 153 fabricated on top of the fin structures 151.

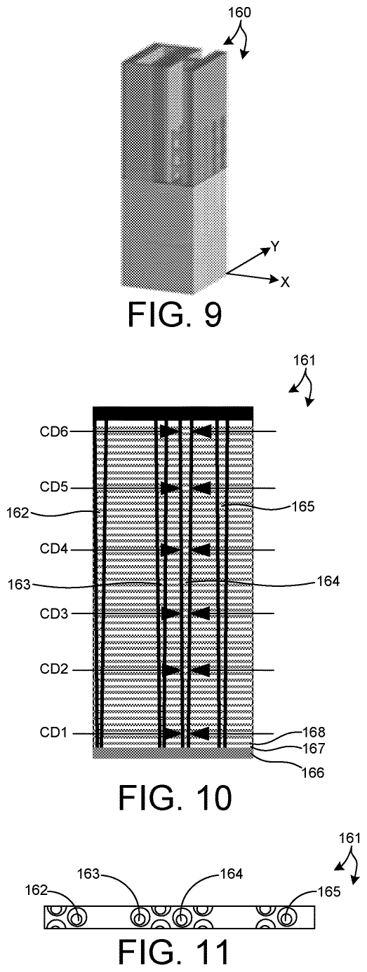

FIG. 9 is a diagram illustrative of perspective view of a three dimensional Gate All Around (GAA) logic target 160 employed to characterize various critical dimensions and thickness and material growth quality. As depicted in FIG. 9, GAA logic target 160 exhibits periodicity in both the x and y directions.

FIG. 10 is a diagram illustrative of a cross-sectional view of a three dimensional memory target 161 employed to characterize various critical dimensions and thickness and material growth quality. Memory target 161 includes a substrate 166 and a large number of alternating material layers 167 and 168. In addition, memory target 161 includes etched hole structures 162-165. As depicted in FIG. 10, hole structure 164 includes critical dimensions, CD1-CD6 at various depths of hole structure 164.

FIG. 11 is a diagram illustrative of a top facing, cross-sectional view of three dimensional memory target 161 employed to characterize various critical dimensions and thickness and material growth quality. As depicted in FIG. 11, memory target 161 includes etched hole structures 162-165.

Measurements performed with a ML based decorrelation model combined with a physics based measurement model as described herein enable improved measurement performance in a number of different measurement applications.

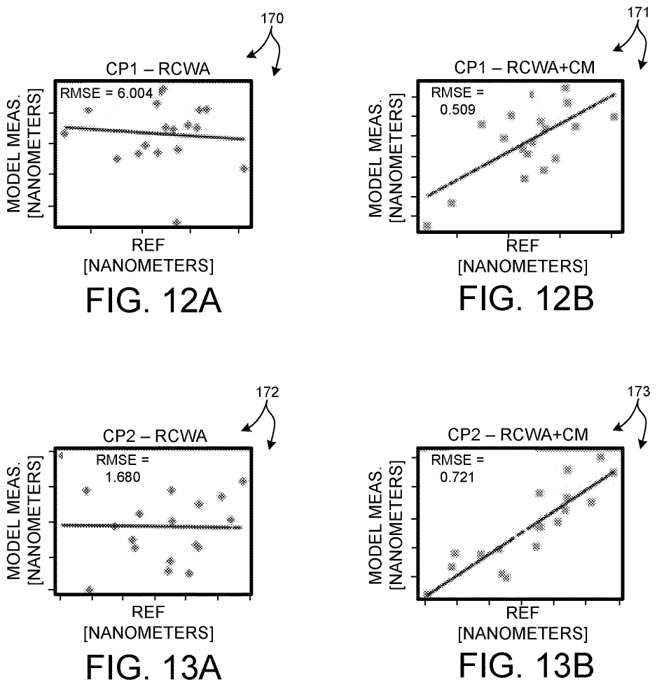

FIG. 12A is a plot 170 illustrating the tracking performance of a physics based measurement model employed to estimate values of a critical parameter, CP1, characterizing a structural aspect of a GAA structure at a nanowire release process step. As illustrated in FIG. 12A, CP1 is measured by the physics based measurement model with very low sensitivity as illustrated by the poor tracking performance, e.g., root mean square error of 6 nanometers.

FIG. 12B is a plot 171 illustrating the tracking performance of a physics based measurement model enhanced by a ML based decorrelation model employed to estimate values of the critical parameter, CP1, illustrated in FIG. 12A. As illustrated in FIG. 12B, CP1 is measured by the physics based measurement model enhanced by a ML based decorrelation model with high sensitivity compared to a physics based measurement model alone, as illustrated by the significantly improved tracking performance, e.g., root mean square error of 0.5 nanometers.

FIG. 13A is a plot 172 illustrating the tracking performance of a physics based measurement model employed to estimate values of a critical parameter, CP2, characterizing a structural aspect of a GAA structure at a nanowire release process step. As illustrated in FIG. 13A, CP2 is measured by the physics based measurement model with very low sensitivity as illustrated by the poor tracking performance, e.g., root mean square error of 1.6 nanometers.

FIG. 13B is a plot 173 illustrating the tracking performance of a physics based measurement model enhanced by a ML based decorrelation model employed to estimate values of the critical parameter, CP2, illustrated in FIG. 13A. As illustrated in FIG. 13B, CP2 is measured by the physics based measurement model enhanced by a ML based decorrelation model with high sensitivity compared to a physics based measurement model alone, as illustrated by the significantly improved tracking performance, e.g., root mean square error of 0.7 nanometers.

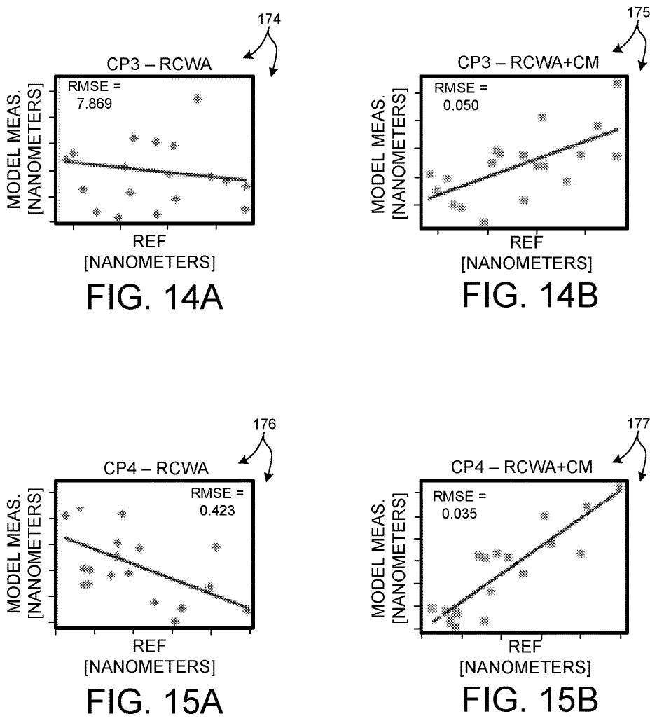

FIG. 14A is a plot 174 illustrating the tracking performance of a physics based measurement model employed to estimate values of a critical parameter, CP3, characterizing a structural aspect of a GAA structure at a Silicon/Silicon Germanium release process step. As illustrated in FIG. 14A, CP3 is measured by the physics based measurement model with very low sensitivity as illustrated by the poor tracking performance, e.g., root mean square error of 7.8 nanometers.

FIG. 14B is a plot 175 illustrating the tracking performance of a physics based measurement model enhanced by a ML based decorrelation model employed to estimate values of the critical parameter, CP3, illustrated in FIG. 14A. As illustrated in FIG. 14B, CP3 is measured by the physics based measurement model enhanced by a ML based decorrelation model with high sensitivity compared to a physics based measurement model alone, as illustrated by the significantly improved tracking performance, e.g., root mean square error of 0.05 nanometers.

FIG. 15A is a plot 176 illustrating the tracking performance of a physics based measurement model employed to estimate values of a critical parameter, CP4, characterizing a structural aspect of a GAA structure at a Silicon/Silicon Germanium release process step. As illustrated in FIG. 15A, CP4 is measured by the physics based measurement model with very low sensitivity as illustrated by the poor tracking performance, e.g., root mean square error of 0.4 nanometers.

FIG. 15B is a plot 177 illustrating the tracking performance of a physics based measurement model enhanced by a ML based decorrelation model employed to estimate values of the critical parameter, CP4, illustrated in FIG. 15A. As illustrated in FIG. 15B, CP4 is measured by the physics based measurement model enhanced by a ML based decorrelation model with high sensitivity compared to a physics based measurement model alone, as illustrated by the significantly improved tracking performance, e.g., root mean square error of 0.035 nanometers.

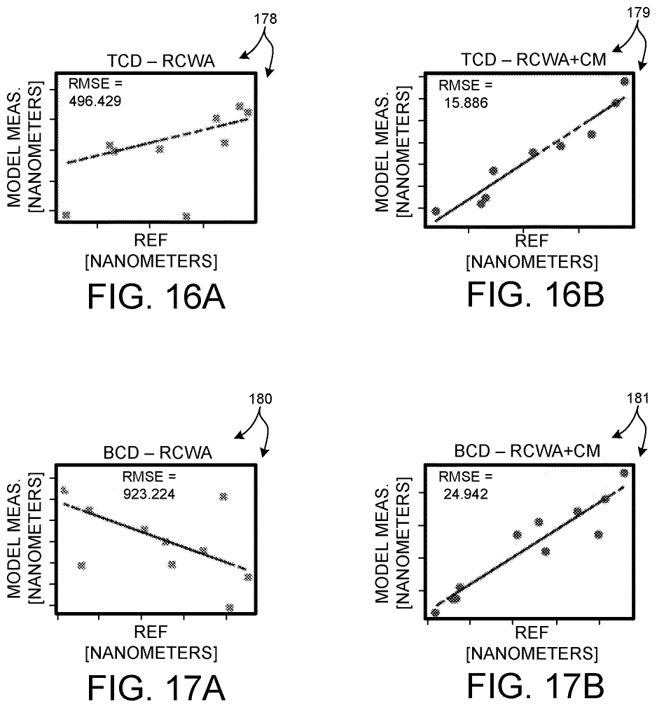

FIG. 16A is a plot 178 illustrating the tracking performance of a physics based measurement model employed to estimate values of a Top Critical Dimension (TCD) of a deep trench structure. As illustrated in FIG. 16A, TCD is measured by the physics based measurement model with very low sensitivity as illustrated by the poor tracking performance, e.g., root mean square error of 496 nanometers.

FIG. 16B is a plot 179 illustrating the tracking performance of a physics based measurement model enhanced by a ML based decorrelation model employed to estimate values of TCD illustrated in FIG. 16A. As illustrated in FIG. 16B, TCD is measured by the physics based measurement model enhanced by a ML based decorrelation model with high sensitivity compared to a physics based measurement model alone, as illustrated by the significantly improved tracking performance, e.g., root mean square error of 15.8 nanometers.

FIG. 17A is a plot 180 illustrating the tracking performance of a physics based measurement model employed to estimate values of a Bottom Critical Dimension (BCD) of a deep trench structure. As illustrated in FIG. 17A, BCD is measured by the physics based measurement model with very low sensitivity as illustrated by the poor tracking performance, e.g., root mean square error of 923 nanometers.

FIG. 17B is a plot 181 illustrating the tracking performance of a physics based measurement model enhanced by a ML based decorrelation model employed to estimate values of BCD illustrated in FIG. 17A. As illustrated in FIG. 17B, BCD is measured by the physics based measurement model enhanced by a ML based decorrelation model with high sensitivity compared to a physics based measurement model alone, as illustrated by the significantly improved tracking performance, e.g., root mean square error of 24.9 nanometers.

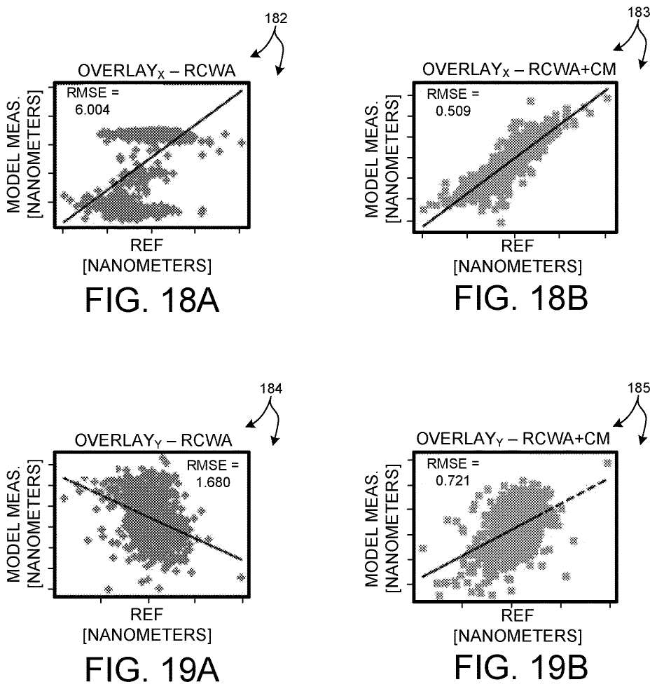

FIG. 18A is a plot 182 illustrating the tracking performance of a physics based measurement model employed to estimate values of in-die overlay in the x-direction (Overlayₓ). As illustrated in FIG. 18A, Overlayₓ is measured by the physics based measurement model with very low sensitivity as illustrated by the poor tracking performance, e.g., root mean square error of 6 nanometers.

FIG. 18B is a plot 183 illustrating the tracking performance of a physics based measurement model enhanced by a ML based decorrelation model employed to estimate values of Overlayₓ illustrated in FIG. 18A. As illustrated in FIG. 18B, Overlayₓ is measured by the physics based measurement model enhanced by a ML based decorrelation model with high sensitivity compared to a physics based measurement model alone, as illustrated by the significantly improved tracking performance, e.g., root mean square error of 0.5 nanometers.

FIG. 19A is a plot 184 illustrating the tracking performance of a physics based measurement model employed to estimate values of in-die overlay in the y-direction (Overlay_{y}). As illustrated in FIG. 19A, Overlay_{y} is measured by the physics based measurement model with very low sensitivity as illustrated by the poor tracking performance, e.g., root mean square error of 1.6 nanometers.

FIG. 19B is a plot 185 illustrating the tracking performance of a physics based measurement model enhanced by a ML based decorrelation model employed to estimate values of Overlay_{y} illustrated in FIG. 19A. As illustrated in FIG. 19B, Overlay_{y} is measured by the physics based measurement model enhanced by a ML based decorrelation model with high sensitivity compared to a physics based measurement model alone, as illustrated by the significantly improved tracking performance, e.g., root mean square error of 0.7 nanometers.

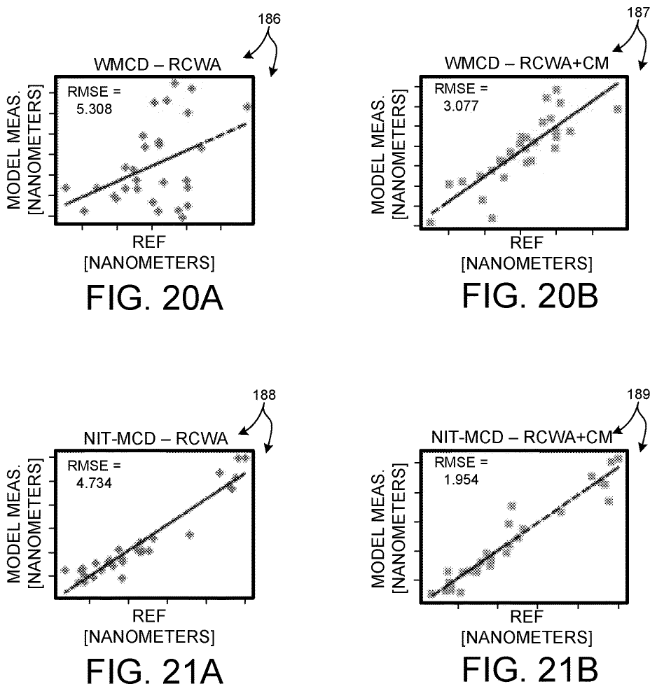

FIG. 20A is a plot 186 illustrating the tracking performance of a physics based measurement model employed to estimate values of a Tungsten Middle Critical Dimension (WMCD) of a DRAM memory structure. As illustrated in FIG. 20A, WMCD is measured by the physics based measurement model with very low sensitivity as illustrated by the poor tracking performance, e.g., root mean square error of 5.3 nanometers.

FIG. 20B is a plot 187 illustrating the tracking performance of a physics based measurement model enhanced by a ML based decorrelation model employed to estimate values of WMCD illustrated in FIG. 20A. As illustrated in FIG. 20B, WMCD is measured by the physics based measurement model enhanced by a ML based decorrelation model with high sensitivity compared to a physics based measurement model alone, as illustrated by the significantly improved tracking performance, e.g., root mean square error of 3 nanometers.

FIG. 21A is a plot 188 illustrating the tracking performance of a physics based measurement model employed to estimate values of a Nitride layer Middle Critical Dimension (NitMCD) of a DRAM memory structure. As illustrated in FIG. 21A, NitMCD is measured by the physics based measurement model with very low sensitivity as illustrated by the poor tracking performance, e.g., root mean square error of 4.7 nanometers.

FIG. 21B is a plot 189 illustrating the tracking performance of a physics based measurement model enhanced by a ML based decorrelation model employed to estimate values of NitMCD illustrated in FIG. 21A. As illustrated in FIG. 21B, NitMCD is measured by the physics based measurement model enhanced by a ML based decorrelation model with high sensitivity compared to a physics based measurement model alone, as illustrated by the significantly improved tracking performance, e.g., root mean square error of 1.9 nanometers.

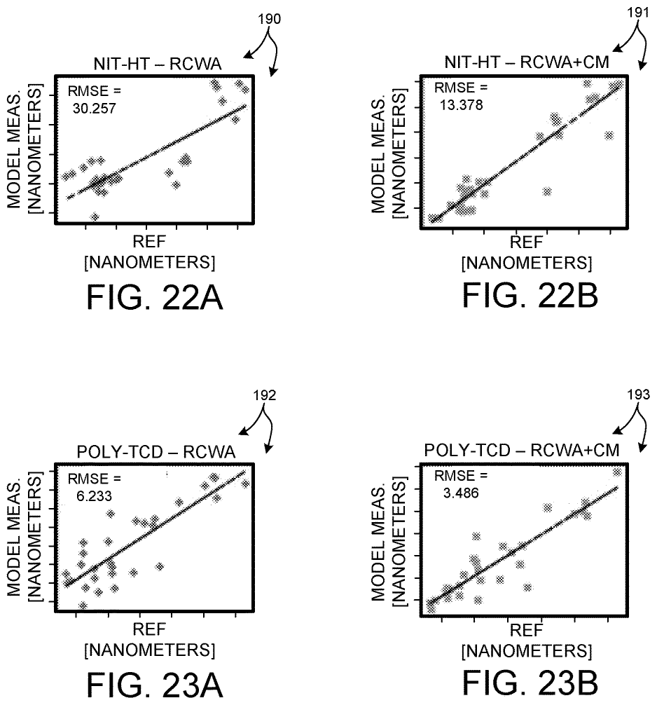

FIG. 22A is a plot 190 illustrating the tracking performance of a physics based measurement model employed to estimate values of a Nitride Height (NitHT) of a DRAM memory structure. As illustrated in FIG. 22A, NitHT is measured by the physics based measurement model with very low sensitivity as illustrated by the poor tracking performance, e.g., root mean square error of 30.2 nanometers.

FIG. 22B is a plot 191 illustrating the tracking performance of a physics based measurement model enhanced by a ML based decorrelation model employed to estimate values of NitHT illustrated in FIG. 22A. As illustrated in FIG. 22B, NitHT is measured by the physics based measurement model enhanced by a ML based decorrelation model with high sensitivity compared to a physics based measurement model alone, as illustrated by the significantly improved tracking performance, e.g., root mean square error of 13 nanometers.

FIG. 23A is a plot 192 illustrating the tracking performance of a physics based measurement model employed to estimate values of a Poly Top Critical Dimension (PolyTCD) of a DRAM memory structure. As illustrated in FIG. 23A, PolyTCD is measured by the physics based measurement model with very low sensitivity as illustrated by the poor tracking performance, e.g., root mean square error of 6.2 nanometers.

FIG. 23B is a plot 193 illustrating the tracking performance of a physics based measurement model enhanced by a ML based decorrelation model employed to estimate values of PolyTCD illustrated in FIG. 23A. As illustrated in FIG. 23B, PolyTCD is measured by the physics based measurement model enhanced by a ML based decorrelation model with high sensitivity compared to a physics based measurement model alone, as illustrated by the significantly improved tracking performance, e.g., root mean square error of 3.4 nanometers.

As depicted in FIGS. 12-23, measurements performed using the physics based measurement model enhanced by a ML based decorrelation model exhibits dramatically improved tracking performance for the expected skew conditions, and more accurately predicts the reference profile. Moreover, the time to solution, i.e., time to complete all training tasks, for the physics based measurement model enhanced by a ML based decorrelation model as illustrated in FIGS. 12-23, is significantly less, e.g., one day, compared to the time to solution for the physics based measurement model only, e.g., more than one week.

As depicted in FIGS. 12A-23A, the physics based measurement model alone exhibits high correlation of the critical parameters to another degree of freedom. This limits the precision of critical parameter measurements as illustrated by the inability of the measurements illustrated in FIGS. 12A-23A to reproduce the specific critical parameter process skew. In contrast, the physics based measurement model enhanced by a ML based decorrelation model breaks the correlation between various critical parameters and other degrees of freedom. This enables measurement accuracy that is otherwise not achieved as illustrated by the ability of the measurements illustrated in FIGS. 12B-23B to reproduce the specific critical parameter process skew.

Measurement results achieved in accordance with the techniques described herein have been validated with reference data across several use cases. Evaluation of tracking performance against reference data demonstrates achieved measurement accuracy. Comparison of lot-to-lot measurement results demonstrates measurement robustness to process variation and achieved measurement precision.

The methods and systems described herein are applicable to a wide range of contactless and non-destructive measurement systems, e.g., optical, electron-based, and x-ray based measurement systems, operating in any number of signal modalities, e.g., reflectometry, ellipsometry, scatterometry, pupil imagery, field imagery, hyperspectral imagery, interferometry, etc. In some examples, a Critical Dimension Small-Angle X-ray Scatterometry (CD-SAXS) based metrology system implements an RCWA based measurement model with a trained Machine Learning (ML) based decorrelation model to overcome poor sensitivity and improve measurement accuracy and robustness. In other examples, a Soft X-ray based metrology system implements an RCWA based measurement model with a trained Machine Learning (ML) based decorrelation model to overcome poor sensitivity and improve measurement accuracy and robustness.

Enhanced model based measurements as described herein breaks correlations and provides sensitivity to structural parameters that would not otherwise be accessible by contactless and non-destructive measurement systems. Exemplary parameters of interest include, but are not limited to, critical dimensions, film thicknesses, overlay dimensions, optical properties of a material, electrical properties of a material, mechanical properties of a material, thermal properties of a material, etc.

In general, the SE metrology system described with reference to FIG. 1 may be any form of a spectroscopic ellipsometer including, but not limited to, a rotating compensator SE system, a rotating polarizer SE system, a rotating polarizer, rotating compensator SE system, a rotating compensator, rotating compensator SE system, a laser modulation SE system, etc. In addition, the enhanced measurement model based measurement techniques may be applied to other ellipsometric systems that employ non-rotating, solid state devices such as photo-elastic modulators to measure all or a portion of the sample Mueller matrix.

The methods and systems described herein enable improved measurements of structural elements common in semiconductor manufacturing, e.g., material composition, alloy fraction measurements of compound semiconductors, material band gap, characterization of semiconductor surfaces and interfaces, film layer properties, critical dimensions, etc. Measurement applications include measurements of structural elements comprising complex semiconductor structures such as 3D VNAND structures and Gate-All-Around (GAA) structures, including front-end-of-line (FEOL) layers from oxide definition layers to high-k metal gate (HKMG) stacks. Measurement applications include measurements of structural elements comprised of semiconducting materials, insulating dielectric materials, and conducting materials, including organic materials, inorganic materials, or a combination thereof.

In general, the techniques to break correlations as described herein may be combined to improve the accuracy of measurements of complex semiconductor structures. For example, enhanced model based measurements of structures at various wavelengths, angles of incidence, azimuth angles, or any combination thereof can be analyzed sequentially or in parallel to accurately decorrelate structural features associated with complex multi-layer structures.

In a further aspect, the wavelengths emitted by the measurement illumination source, e.g., illumination source 110, are selectable. In some embodiments, illumination source 110 is a LSP light source controlled by computing system 130 to maximize flux in one or more selected spectral regions. Laser peak intensity at the target material controls the plasma temperature and thus the spectral region of emitted radiation. Laser peak intensity is varied by adjusting pulse energy, pulse width, or both. As depicted in FIG. 1, computing system 130 communicates command signal 140 to illumination source 110 that causes illumination source 110 to adjust the spectral range of wavelengths emitted from illumination source 110.

In some examples, the enhanced decorrelation measurement engine 200 reads a file that contains the equations describing the shape and composition of the structure under measurement. In some examples, this file is generated by a lithography simulator such as PROLITH software available from KLA Corporation, Milpitas, California (USA). Based on this application information the enhanced decorrelation measurement engine automatically sets the parameterization and constraints of the structural model.

Although the methods discussed herein are explained with reference to system 100, any optical or x-ray based metrology system configured to illuminate and detect light scattered from a specimen may be employed to implement the exemplary methods described herein. Furthermore, any electron based metrology system configured to illuminate a sample with one or more illumination beams of electrons and detect scattered electrons from a specimen may be employed to implement the exemplary methods described herein. Exemplary systems include an angle-resolved reflectometer (i.e., a beam profile reflectometer), an angle-resolved ellipsometer (i.e., beam profile ellipsometer), an angle-resolved reflectometer, a scatterometer, a spectroscopic reflectometer or ellipsometer, a spectroscopic reflectometer or ellipsometer with multiple angles of illumination, a Mueller Matrix spectroscopic ellipsomenter (e.g., a rotating compensator spectroscopic ellipsometer), a single wavelength ellipsometer, a single wavelength reflectometer, a RAMAN scatterometer, a transmission, small-angle x-ray scatterometer, a reflective, small-angle x-ray scatterometer, a grazing incidence, small-angle x-ray scatterometer, a soft X-ray based metrology system, a laser modulated scatterometer, a transmission electron microscope, a scanning electron microscope, electron beam inspection systems, electron beam metrology systems, including multiple beam systems, etc.

By way of non-limiting example, an ellipsometer may include a single rotating compensator, multiple rotating compensators, a rotating polarizer, a rotating analyzer, a modulating element, multiple modulating elements, or no modulating element.

It is noted that the output from a target measurement system may be configured in such a way that the measurement system uses more than one technology. In fact, an application may be configured to employ any combination of available metrology sub-systems within a single tool, or across a number of different tools.

A system implementing the methods described herein may also be configured in a number of different ways. For example, a wide range of wavelengths (including visible, ultraviolet, and infrared), angles of incidence, states of polarization, and states of coherence may be contemplated. In another example, the system may include any of a number of different light sources (e.g., a directly coupled light source, a laser-sustained plasma light source, etc.). In another example, the system may include elements to condition light directed to or collected from the specimen (e. g., apodizers, filters, etc.).

In general, the optical dispersion properties of semiconductor structures under measurement may be approximated as isotropic. Under this assumption the material parameters are scalar values. Alternatively, the optical dispersion properties of semiconductor structures under measurement may be more accurately modelled as anisotropic. Under this assumption, the material parameters will be a matrix of different values, rather than a scalar value. Additional details regarding the treatment of anisotropic structures under measurement is described in U.S. Patent Publication No. 2018/0059019, the content of which is incorporated herein by reference in its entirety.

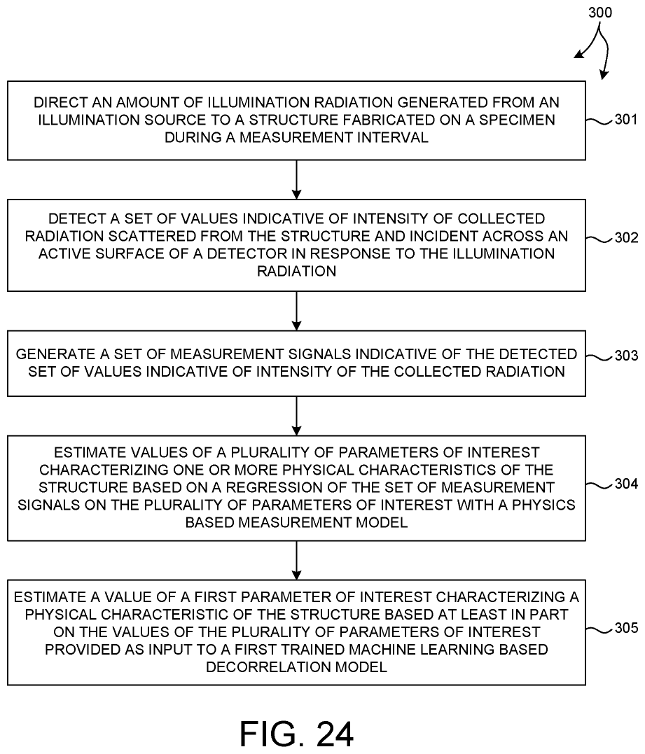

FIG. 24 illustrates a method 300 suitable for implementation by the metrology system 100 of the present invention. In one aspect, it is recognized that data processing blocks of method 300 may be carried out via a pre-programmed algorithm executed by one or more processors of computing system 130. While the following description is presented in the context of metrology system 100, it is recognized herein that the particular structural aspects of metrology system 100 do not represent limitations and should be interpreted as illustrative only.

In block 301, an amount of illumination radiation generated from an illumination source is directed to a structure fabricated on a specimen during a measurement interval.

In block 302, a set of values indicative of intensity of collected radiation scattered from the structure and incident across an active surface of the detector in response to the illumination radiation is detected.

In block 303, a set of measurement signals indicative of the detected set of values indicative of intensity of the collected radiation is generated.

In block 304, values of a plurality of parameters of interest characterizing one or more physical characteristics of the structure are generated based on a regression of the set of measurement signals on the plurality of parameters of interest with a physics based measurement model.

In block 305, a value of a first parameter of interest characterizing a physical characteristic of the structure is estimated based at least in part on the values of the plurality of parameters of interest provided as input to a first trained machine learning based decorrelation model.

It should be recognized that the various steps described throughout the present disclosure may be carried out by a single computer system, or, alternatively, multiple computer systems. Moreover, different subsystems, such as the spectroscopic ellipsometer 105, may include a computer system suitable for carrying out at least a portion of the steps described herein. Therefore, the aforementioned description should not be interpreted as a limitation on the present invention but merely an illustration. Further, the one or more computing systems 130 may be configured to perform any other step(s) of any of the method embodiments described herein.

The computing system 130 may include, but is not limited to, a cloud based computing system, a personal computer system, mainframe computer system, workstation, image computer, parallel processor, or any other computing device known in the art. In general, the term “computing system” may be broadly defined to encompass any device having one or more processors, which execute instructions from a memory medium. In general, computing system 130 may be integrated with a measurement system such as measurement system 100, or alternatively, may be separate from any measurement system. In this sense, computing system 130 may be remotely located and receive measurement data and user input from any measurement source and user input source, respectively.

Program instructions 134 implementing methods such as those described herein may be transmitted over or stored on carrier medium. The carrier medium may be a transmission medium such as a wire, cable, or wireless transmission link. The carrier medium may also include a computer-readable medium such as a read-only memory, a random access memory, a magnetic or optical disk, or a magnetic tape. For example, as illustrated in FIG. 3, program instructions 134 stored in memory 132 are transmitted to processor 131 over bus 133. Program instructions 134 are stored in a computer readable medium (e.g., memory 132). Exemplary computer-readable media include read-only memory, a random access memory, a magnetic or optical disk, or a magnetic tape.

In yet another aspect, the measurement results described herein can be used to provide active feedback to a process tool (e.g., lithography tool, etch tool, deposition tool, etc.). For example, values of measured parameters determined based on measurement methods described herein can be communicated to a lithography tool to adjust the lithography system (e.g., focus, dosage, etc.) to achieve a desired output. In a similar way etch parameters (e.g., etch time, diffusivity, etc.) or deposition parameters (e.g., time, concentration, etc.) may be adjusted based on values of measured parameters determined based on measurement methods described herein. In some examples, corrections to process parameters determined based on measured device parameter values may be communicated to a lithography tool, etch tool, or deposition tool.

As described herein, the term “critical dimension” includes any critical dimension of a structure (e.g., bottom critical dimension, middle critical dimension, top critical dimension, sidewall angle, grating height, trench depth, etc.), a critical dimension between any two or more structures (e.g., distance between two structures), a displacement between two or more structures (e.g., overlay displacement between overlaying grating structures, etc.), and a dispersion property value of a material used in the structure or part of the structure. Structures may include three dimensional structures, patterned structures, overlay structures, etc.

As described herein, the term “critical dimension application” or “critical dimension measurement application” includes any critical dimension measurement.

As described herein, the term “metrology system” includes any system employed at least in part to characterize a specimen in any aspect. However, such terms of art do not limit the scope of the term “metrology system” as described herein. The metrology system may be configured as a LED inspection tool, edge inspection tool, backside inspection tool, macro-inspection tool, or multi-mode inspection tool (involving data from one or more platforms simultaneously), and any other metrology or inspection tool.

Various embodiments are described herein for a semiconductor processing system (e.g., an inspection system or a lithography system) that may be used for processing a specimen. The term “specimen” is used herein to refer to a site, or sites, on a wafer, a reticle, or any other sample that may be processed (e.g., printed, measured, or inspected for defects) by means known in the art. In some examples, the specimen includes a single site having one or more measurement targets whose simultaneous, combined measurement is treated as a single specimen measurement or reference measurement. In some other examples, the specimen is an aggregation of sites where the measurement data associated with the aggregated measurement site is a statistical aggregation of data associated with each of the multiple sites. Moreover, each of these multiple sites may include one or more measurement targets associated with a specimen or reference measurement.

As used herein, the term “wafer” generally refers to substrates formed of a semiconductor or non-semiconductor material. Examples include, but are not limited to, monocrystalline silicon, gallium arsenide, and indium phosphide. Such substrates may be commonly found and/or processed in semiconductor fabrication facilities. In some cases, a wafer may include only the substrate (i.e., bare wafer). Alternatively, a wafer may include one or more layers of different materials formed upon a substrate. One or more layers formed on a wafer may be “patterned” or “unpatterned.” For example, a wafer may include a plurality of dies having repeatable pattern features.

A “reticle” may be a reticle at any stage of a reticle fabrication process, or a completed reticle that may or may not be released for use in a semiconductor fabrication facility. A reticle, or a “mask,” is generally defined as a substantially transparent substrate having substantially opaque regions formed thereon and configured in a pattern. The substrate may include, for example, a glass material such as amorphous SiO₂. A reticle may be disposed above a resist-covered wafer during an exposure step of a lithography process such that the pattern on the reticle may be transferred to the resist.

One or more layers formed on a wafer may be patterned or unpatterned. For example, a wafer may include a plurality of dies, each having repeatable pattern features. Formation and processing of such layers of material may ultimately result in completed devices. Many different types of devices may be formed on a wafer, and the term wafer as used herein is intended to encompass a wafer on which any type of device known in the art is being fabricated.

In one or more exemplary embodiments, the functions described may be implemented in hardware, software, firmware, or any combination thereof. If implemented in software, the functions may be stored on or transmitted over as one or more instructions or code on a computer-readable medium. Computer-readable media includes both computer storage media and communication media including any medium that facilitates transfer of a computer program from one place to another. A storage media may be any available media that can be accessed by a general purpose or special purpose computer. By way of example, and not limitation, such computer-readable media can comprise RAM, ROM, EEPROM, CD-ROM or other optical disk storage, magnetic disk storage or other magnetic storage devices, or any other medium that can be used to carry or store desired program code means in the form of instructions or data structures and that can be accessed by a general-purpose or special-purpose computer, or a general-purpose or special-purpose processor. Also, any connection is properly termed a computer-readable medium. For example, if the software is transmitted from a website, server, or other remote source using a coaxial cable, fiber optic cable, twisted pair, digital subscriber line (DSL), or wireless technologies such as infrared, radio, and microwave, then the coaxial cable, fiber optic cable, twisted pair, DSL, or wireless technologies such as infrared, radio, and microwave are included in the definition of medium. Disk and disc, as used herein, includes compact disc (CD), laser disc, optical disc, digital versatile disc (DVD), floppy disk and blu-ray disc where disks usually reproduce data magnetically, while discs reproduce data optically with lasers. Combinations of the above should also be included within the scope of computer-readable media.

Although certain specific embodiments are described above for instructional purposes, the teachings of this patent document have general applicability and are not limited to the specific embodiments described above. Accordingly, various modifications, adaptations, and combinations of various features of the described embodiments can be practiced without departing from the scope of the invention as set forth in the claims.

What is claimed is:

1. A metrology system comprising:
an illumination source configured to generate an amount of illumination radiation directed to a structure fabricated on a specimen during a measurement interval;
a detector configured to detect a set of values indicative of intensity of collected radiation scattered from the structure and incident across an active surface of the detector in response to the illumination radiation; and
a computing system configured to:
generate a set of measurement signals indicative of the detected set of values indicative of intensity of the collected radiation;
estimate values of a plurality of parameters of interest characterizing one or more physical characteristics of the structure based on a regression of the set of measurement signals on the plurality of parameters of interest with a physics based measurement model; and
estimate a value of a first parameter of interest characterizing a first physical characteristic of the structure based at least in part on the values of the plurality of parameters of interest provided as input to a first trained machine learning based decorrelation model.

2. The metrology system of claim 1, the computing system further configured to:
estimate a value of a second parameter of interest characterizing a second physical characteristic of the structure based at least in part on the values of the plurality of parameters of interest provided as input to a second trained machine learning based decorrelation model different from the first trained machine learning based decorrelation model.

3. The metrology system of claim 1, the computing system further configured to:
generate a set of seed values of a plurality of parameters of the physics based measurement model by a trained machine learning based seed model based on the measurement signals, wherein the set of seed values are implemented as values of the plurality of parameters of interest employed in at least a first iteration of the regression of the set of measurement signals on the plurality of parameters of interest with the physics based measurement model.

4. The metrology system of claim 1, wherein the estimating of the value of the first parameter of interest characterizing the physical characteristic of the structure is also based on the set of measurement signals.

5. The metrology system of claim 1, wherein the generating of the set of measurement signals indicative of the detected set of values indicative of intensity of the collected radiation involves:
generating an initial set of measurement signals indicative of the detected set of values indicative of intensity of the collected radiation; and
reducing a dimension of the initial set of measurement signals to generate the set measurement signals.

6. The metrology system of claim 1, the computing system further configured to:
train the first machine learning based decorrelation model based on Design of Experiments (DOE) reference data sets including DOE measurements signals and corresponding values of the first parameter of interest.

7. The metrology system of claim 6, wherein the values of the first parameter of interest of the DOE reference data sets are generated by a trusted reference metrology system different from the metrology system.

8. The metrology system of claim 1, the computing system further configured to:
train a machine learning based measurement model based in part on the set of measurement signals and the value of the first parameter of interest, the trained machine learning based measurement model configured to estimate the value of the first parameter of interest directly from the set of measurement signals.

9. The metrology system of claim 1, wherein the first parameter of interest is any of an optical, electrical, mechanical, or thermal property of a material, a critical dimension, or a film thickness.

10. The metrology system of claim 1, wherein the structure under measurement is located below a top surface of the specimen.

11. The metrology system of claim 1, wherein the metrology system is any of a spectroscopic ellipsometry metrology system, a small-angle X-ray scatterometry metrology system, a soft X-ray metrology system, an electron beam metrology system, and a laser modulation based spectroscopic elliposometry metrology system.

12. The metrology system of claim 1, wherein the detected measurement signals are values of one or more Mueller matrix elements.

13. A method comprising:
directing an amount of illumination radiation generated from an illumination source to a structure fabricated on a specimen during a measurement interval;
detecting a set of values indicative of intensity of collected radiation scattered from the structure and incident across an active surface of a detector in response to the illumination radiation;
generating a set of measurement signals indicative of the detected set of values indicative of intensity of the collected radiation;
estimating values of a plurality of parameters of interest characterizing one or more physical characteristics of the structure based on a regression of the set of measurement signals on the plurality of parameters of interest with a physics based measurement model; and
estimating a value of a first parameter of interest characterizing a physical characteristic of the structure based at least in part on the values of the plurality of parameters of interest provided as input to a first trained machine learning based decorrelation model.

14. The method of claim 13, further comprising:
estimating a value of a second parameter of interest characterizing a second physical characteristic of the structure based at least in part on the values of the plurality of parameters of interest provided as input to a second trained machine learning based decorrelation model different from the first trained machine learning based decorrelation model.

15. The method of claim 13, further comprising:
generating a set of seed values of the plurality of parameters of the physics based measurement model by a trained machine learning based seed model based on the set of measurement signals provided as input to the trained machine learning based seed model, wherein the values of the plurality of parameters of interest at a first iteration of the regression of the set of measurement signals on the plurality of parameters of interest with the physics based measurement model are the set of seed values.

16. The method of claim 13, wherein the estimating of the value of the first parameter of interest characterizing the physical characteristic of the structure is also based on the set of measurement signals.

17. The method of claim 13, wherein the generating of the set of measurement signals indicative of the detected set of values indicative of intensity of the collected radiation involves:
generating an initial set of measurement signals indicative of the detected set of values indicative of intensity of the collected radiation; and
reducing a dimension of the initial set of measurement signals to generate the set measurement signals.

18. The method of claim 13, further comprising:
training the first machine learning based decorrelation model based on Design of Experiments (DOE) reference data sets including DOE measurements signals and corresponding values of the first parameter of interest.

19. The method of claim 1, further comprising:
training a machine learning based measurement model based in part on the set of measurement signals and the value of the first parameter of interest, the trained machine learning based measurement model configured to estimate the value of the first parameter of interest directly from the set of measurement signals.

20. A metrology system comprising:
an illumination source configured to generate an amount of illumination radiation directed to a structure fabricated on a specimen during a measurement interval;
a detector configured to detect a set of values indicative of intensity of collected radiation scattered from the structure and incident across an active surface of the detector in response to the illumination radiation; and
a non-transitory, computer-readable medium storing instructions that, when executed by one or more processors, causes the one or more processors to:
generate a set of measurement signals indicative of the detected set of values indicative of intensity of the collected radiation;
estimate values of a plurality of parameters of interest characterizing one or more physical characteristics of the structure based on a regression of the set of measurement signals on the plurality of parameters of interest with a physics based measurement model; and
estimate a value of a first parameter of interest characterizing a physical characteristic of the structure based at least in part on the values of the plurality of parameters of interest provided as input to a first trained machine learning based decorrelation model.
